(19) United States
(12) Patent Application Publication
(10) Pub. No.: US 2024/0234287 A9
(43) Pub. Date: Jul. 11, 2024

(54) SEMICONDUCTOR PACKAGE AND METHOD OF MANUFACTURING THE SEMICONDUCTOR PACKAGE

(71) Applicant: SAMSUNG ELECTRONICS CO., LTD., Suwon-si (KR)

(72) Inventors: Geunwoo KIM, Suwon-si (KR); Sungeun JO, Suwon-si (KR)

(21) Appl. No.: 18/368,760

(22) Filed: Sep. 15, 2023

(30) Foreign Application Priority Data
Oct. 24, 2022 (KR) 10-2022-0137006

(51) Int. Cl. H01L 23/498; H01L 23/00; H01L 23/433; H01L 25/00; H01L 25/18; H10B 80/00

(52) U.S. Cl. CPC H01L 23/49838; H01L 23/4334; H01L 23/49822; H01L 24/16; H01L 24/32; H01L 24/73; H01L 25/18; H01L 25/50; H10B 80/00; H01L 23/3128; H01L 2224/16227; H01L 2224/32221; H01L 2224/73253; H01L 2924/1431; H01L 2924/1432; H01L 2924/1433; H01L 2924/1436; H01L 2924/1437; H01L 2924/1443

(57) ABSTRACT

A semiconductor package includes: a first redistribution wiring layer having first redistribution wirings; a second redistribution wiring layer arranged on the first redistribution wiring layer, and including a first region, a second region, and a second redistribution wirings; a first semiconductor chip arranged on the first region of the second redistribution wiring layer; a plurality of second semiconductor chips spaced apart from each other on the upper surface of the second region of the second redistribution wiring layer; a plurality of third semiconductor chips arranged in the second region of the second redistribution wiring layer and spaced apart from each other between the first and second redistribution wiring layers; and a heat transfer medium arranged on the first region of the second redistribution wiring layer and overlapping the first semiconductor chip with the second redistribution wiring layer interposed between the first semiconductor chip and the heat transfer medium.

### CROSS-REFERENCE TO RELATED APPLICATION

This application claims priority under 35 U.S.C. § 119 to Korean Patent Application No. 10-2022-0137006, filed on Oct. 24, 2022 in the Korean Intellectual Property Office (KIPO), the disclosure of which is incorporated by reference herein in its entirety.

### TECHNICAL FIELD

Example embodiments of the present inventive concept relate to a semiconductor package and a method of manufacturing the semiconductor package. More particularly, example embodiments of the present inventive concept relate to a multi-chip package including a plurality of different stacked chips and a method of manufacturing the same.

### DISCUSSION OF THE RELATED ART

In a 2.1D, 2.5D or 3D package, as the number of memory chips mounted in a molded interposer (MIP) increases, the size of the interposer increases, and accordingly, when the molded interposer is mounted on a package substrate, non-wet defects may occur in a reflow process. Accordingly, a structure that is capable of increasing the number of mounted memory chips without increasing the size of the package and optimizing heat dissipation characteristics is desirable.

### SUMMARY

According to an example embodiment of the present inventive concept, a semiconductor package includes: a first redistribution wiring layer having first redistribution wirings; a second redistribution wiring layer arranged on the first redistribution wiring layer, and including a first region and a second region, wherein the second redistribution wiring layer includes second redistribution wirings; a first semiconductor chip arranged on one of an upper surface or a lower surface of the first region of the second redistribution wiring layer; a plurality of second semiconductor chips spaced apart from each other on the upper surface of the second region of the second redistribution wiring layer; a plurality of third semiconductor chips arranged in the second region of the second redistribution wiring layer and spaced apart from each other between the first and second redistribution wiring layers; and a heat transfer medium arranged on one of the upper surface or the lower surface of the first region of the second redistribution wiring layer and overlapping the first semiconductor chip with the second redistribution wiring layer interposed between the first semiconductor chip and the heat transfer medium.

According to an example embodiment of the present inventive concept, a semiconductor package includes: an upper redistribution wiring layer including a first region and a second region at least partially surrounding the first region, and having upper redistribution wirings; a first semiconductor chip arranged on one of an upper surface or a lower surface of the first region of the upper redistribution wiring layer; a plurality of second semiconductor chips spaced apart from each other on an upper surface of the second region of the upper redistribution wiring layer; a plurality of third semiconductor chips spaced apart from each other on a lower surface of the second region of the upper redistribution wiring layer, a first sealing member disposed on the plurality of third semiconductor chips and disposed on the upper redistribution wiring layer; a heat transfer medium arranged on one of the upper surface or the lower surface of the first region of the upper redistribution wiring layer and overlapping the first semiconductor chip, wherein the heat transfer medium is provided in the first sealing member; and a lower redistribution wiring layer overlapping a lower surface of the first sealing member and having lower redistribution wirings electrically connected to the upper redistribution wirings.

According to an example embodiment of the present inventive concept, a semiconductor package includes: a package substrate; a first redistribution wiring layer mounted on the package substrate via conductive bumps and having first redistribution wirings; a second redistribution wiring layer arranged on the first redistribution wiring layer, and including a first region and a second region at least partially surrounding the first region, wherein the second redistribution wiring layer has second redistribution wirings; a first semiconductor chip mounted on an upper surface of the first region of the second redistribution wiring layer; a plurality of second semiconductor chips mounted on an upper surface of the second region of the second redistribution wiring layer and spaced apart from each other; a plurality of third semiconductor chips mounted on a lower surface of the second region of the second redistribution wiring layer and spaced apart from each other between the first and second redistribution wiring layers; a first sealing member covering the plurality of third semiconductor chips and disposed on the lower surface of the second redistribution wiring layer; a second sealing member covering the first semiconductor chip and the plurality of second semiconductor chips and disposed on the upper surface of the second redistribution wiring layer; and a plurality of through plugs extending to penetrate the first sealing member, which is disposed on a lower surface of the first region of the second redistribution wiring layer, and electrically connecting the first and second redistribution wirings to each other.

### BRIEF DESCRIPTION OF THE DRAWINGS

The above and other features of the present inventive concept will become more apparent by describing in detail example embodiments thereof, with reference to the accompanying drawings, in which:

FIG. 1 is a cross-sectional view illustrating a semiconductor package in accordance with an example embodiment of the present inventive concept.

FIG. 2 is a plan view illustrating a first semiconductor chip and a plurality of second semiconductor chips disposed on an upper surface of a second redistribution wiring layer in FIG. 1.

FIG. 3 is a plan view illustrating a plurality of third semiconductor chips and a plurality of heat transfer plugs disposed on a lower surface of the second redistribution wiring layer in FIG. 1.

FIGS. 4, 5, 6, 7, 8, 9, 10, 11, 12, 13, 14, 15 and 16 are views illustrating a method of manufacturing a semiconductor package in accordance with an example embodiment of the present inventive concept.

FIG. 17 is a cross-sectional view illustrating a semiconductor package in accordance with an example embodiment of the present inventive concept.

FIG. 18 is a cross-sectional view illustrating the semiconductor package in FIG. 17.

FIG. 19 is a plan view illustrating a first semiconductor chip and a plurality of second semiconductor chips disposed on an upper surface of a second redistribution wiring layer of FIGS. 17 and 18.

FIG. 20 is a plan view illustrating a plurality of third semiconductor chips, a plurality of heat transfer plugs and a heat transfer dummy chip disposed on a lower surface of the second redistribution wiring layer of FIGS. 17 and 18.

FIGS. 21, 22, 23, 24, 25, and 26 are views illustrating a method of manufacturing a semiconductor package in accordance with an example embodiment of the present inventive concept.

FIG. 27 is a cross-sectional view illustrating a semiconductor package in accordance with an example embodiment of the present inventive concept.

FIG. 28 is an enlarged cross-sectional view illustrating portion ‘K’ in FIG. 27.

FIG. 29 is an enlarged cross-sectional view illustrating portion ‘L’ in FIG. 27.

FIG. 30 is a cross-sectional view illustrating a semiconductor package in accordance with an example embodiment of the present inventive concept.

FIG. 31 is a plan view illustrating a heat transfer dummy chip and a plurality of second semiconductor chips disposed on an upper surface of a second redistribution wiring layer in FIG. 30.

FIG. 32 is a plan view illustrating a first semiconductor chip and a plurality of third semiconductor chips disposed on a lower surface of the second redistribution wiring layer in FIG. 30.

FIG. 33 is a cross-sectional view illustrating a semiconductor package in accordance with an example embodiment of the present inventive concept.

FIG. 34 is a plan view illustrating heat transfer plugs and a plurality of second semiconductor chips disposed on an upper surface of a second redistribution wiring layer in FIG. 33.

FIG. 35 is a plan view illustrating a first semiconductor chip and a plurality of third semiconductor chips disposed on a lower surface of the second redistribution wiring layer in FIG. 33.

FIG. 36 is a cross-sectional view illustrating a semiconductor package in accordance with an example embodiment of the present inventive concept.

FIG. 37 is a cross-sectional view illustrating a semiconductor package in accordance with an example embodiment of the present inventive concept.

### DETAILED DESCRIPTION OF THE EMBODIMENTS

Hereinafter, example embodiments of the present inventive concept will be explained in detail with reference to the accompanying drawings.

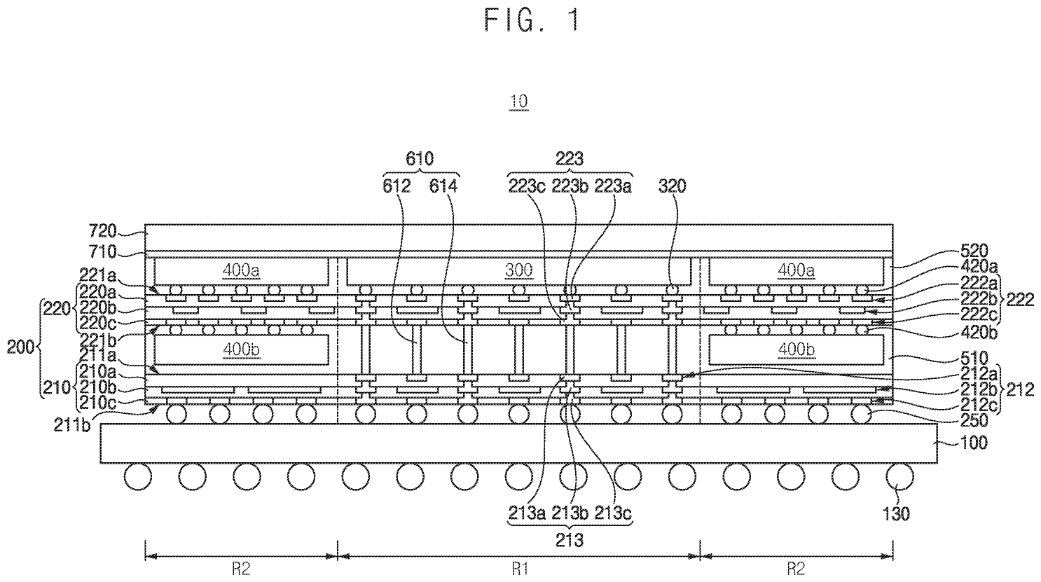

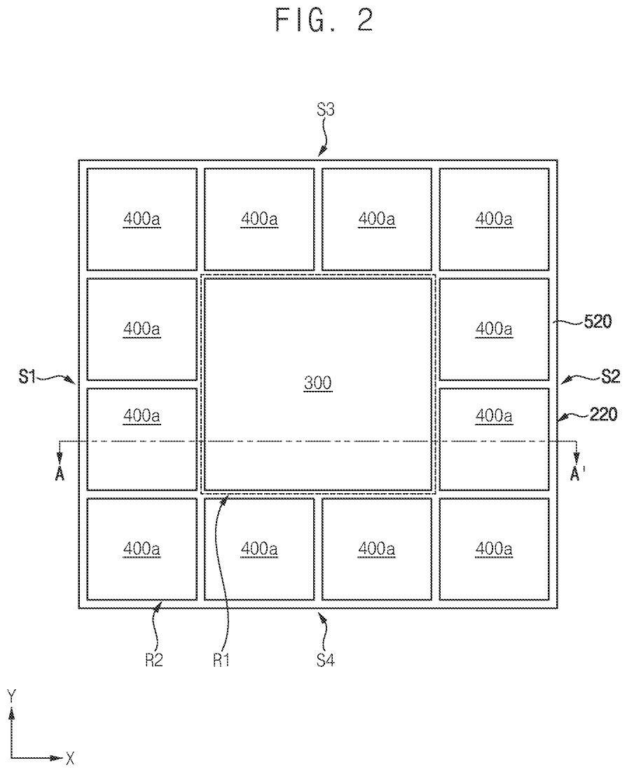

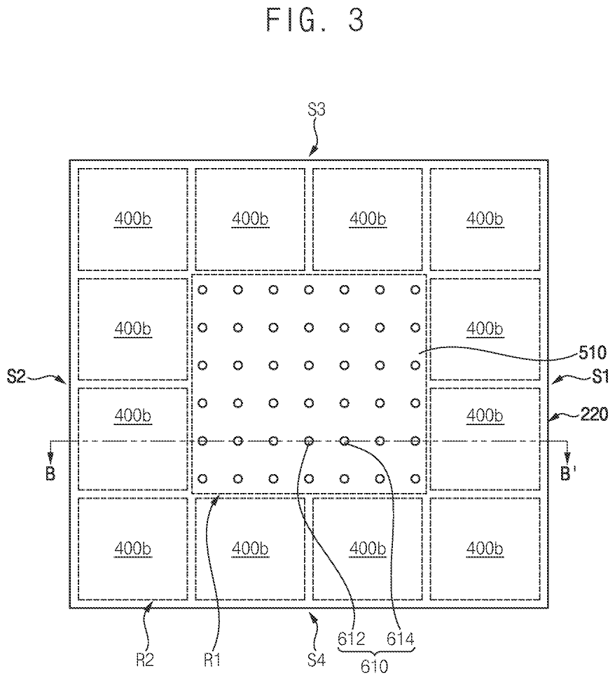

FIG. 1 is a cross-sectional view illustrating a semiconductor package in accordance with an example embodiment of the present inventive concept. FIG. 2 is a plan view illustrating a first semiconductor chip and a plurality of second semiconductor chips disposed on an upper surface of a second redistribution wiring layer in FIG. 1. FIG. 3 is a plan view illustrating a plurality of third semiconductor chips and a plurality of heat transfer plugs disposed on a lower surface of the second redistribution wiring layer in FIG. 1. FIG. 1 is a cross-sectional view taken along the line A-A′ in FIG. 2 and the line B-B′ in FIG. 3.

Referring to FIGS. 1 to 3, a semiconductor package 10 may include a package substrate 100 and a molded interposer 200 in which a first semiconductor chip 300 and a plurality of second and third semiconductor chips 400a and 400b are mounted. The semiconductor package 10 may further include external connection members 130. The interposer 200 may include a first redistribution wiring layer 210, a second redistribution wiring layer 220 stacked on the first redistribution wiring layer 210, the first semiconductor chip 300 and the plurality of second semiconductor chips 400a disposed on the second redistribution wiring layer 220, and the plurality of third semiconductor chips 400b and a plurality of through plugs 610 as heat transfer plugs arranged between the first redistribution wiring layer 210 and the second redistribution wiring layer 220.

In addition, the semiconductor package 10 may be a multi-chip package (MCP) including different types of semiconductor chips. The semiconductor package 10 may be a system in package (SIP) having an independent function by stacking or arranging a plurality of semiconductor chips in one package. For example, the semiconductor package 10 may include a semiconductor memory device having a 2.1D, 2.5D or 3D chip structure.

In some example embodiments of the present inventive concept, the interposer 200 may include the first and second redistribution wiring layers 210 and 220 that are stacked as an organic interposer or a redistribution wiring interposer. The first redistribution wiring layer 210 may be a lower redistribution wiring interposer, and the second redistribution wiring layer 220 may be an upper redistribution wiring interposer. The second redistribution wiring layer 220 may be disposed on the first redistribution wiring layer 210.

As illustrated in FIGS. 2 and 3, the interposer 200 may include a first side portion S1 and a second side portion S2 extending in a direction parallel with a second direction (Y direction) and opposite to each other. The interposer 200 may further include a third side portion S3 and a fourth side portion S4 extending in a direction parallel with a first direction (X direction) perpendicular to the second direction and opposite to each other.

The interposer 200 may include a first region R1, which is located in a central region of the interposer 200, and a second region R2, which at least partially surrounds the first region R1. The first region R1 may be a region that overlaps the first semiconductor chip 300, which is disposed on the second redistribution wiring layer 220, and the second region R2 may be a region that overlaps the plurality of second semiconductor chips 400a, which are disposed on the second redistribution wiring layer 220, and the plurality of third semiconductor chips 400b, which are disposed below the second redistribution wiring layer 220.

In some example embodiments of the present inventive concept, the first redistribution wiring layer 210 may include first redistribution wiring layers 212 that may include at least two stacked layers. The first redistribution wiring layer 210 may include first, second and third lower insulating layers 210a. 210b and 210c and first redistribution wirings 212. The first, second and third lower insulating layers 210a. 210b and 210c may be sequentially stacked on one another, and the first redistribution wirings 212 may be disposed in the first, second and third lower insulating layers 210a, 210b and 210c. The first redistribution wirings 212 may include first, second and third lower redistribution wirings 212a, 212b and 212c. The first redistribution wiring layer 210 may have a first surface 211a and a second surface 211b opposite to the first surface 211b.

The second redistribution wiring layer 220 may include second redistribution wirings 222 that may include at least two stacked layers. For example, the second redistribution wiring layer 220 may include first, second and third upper insulating layers 220a, 220b and 220c and second redistribution wirings 222. The first, second and third upper insulating layers 220a, 220b and 220c may be sequentially stacked on one another, and the second redistribution wirings 222 may be disposed in the first, second and third upper insulating layers 220a, 220b and 220c. The second redistribution wirings 222 may include first, second and third upper redistribution wirings 222a, 222b and 222c. The second redistribution wiring layer 220 may have a first surface 221a and a second surface 221b opposite to the first surface 221a.

For example, the first, second and third lower insulating layers 210a, 210b, and 210c and the first, second and third upper insulating layers 220a. 220b, and 220c may include a polymer or a dielectric layer. The first and second redistribution wirings may include, for example, copper (Cu), aluminum (Al), tin (Sn), nickel (Ni), gold (Au), platinum (Pt), or an alloy thereof.

The numbers, sizes, arrangements, etc. of the insulating layers 210a. 210b, 210c, 220a, 220b, and 220c and the redistribution wirings 212a, 212b, 212c, 222a, 222b and 222c of the first and second redistribution wiring layers 210 and 220 are provided as examples, and it will be understood that the present inventive concept is not limited thereto.

In some example embodiments of the present inventive concept, the first semiconductor chip 300 may be disposed in the first region R1 and on the first surface 221a of the second redistribution wiring layer 220, and the plurality of second semiconductor chips 400a may be spaced apart from each other within the second region R2 and on the first surface 221a of the second redistribution wiring layer 220. The plurality of second semiconductor chips 400a may be spaced apart from each other along a perimeter of the first semiconductor chip 300.

The first semiconductor chip 300 and the plurality of second semiconductor chips 400a may be mounted on the first surface 221a of the second redistribution wiring layer 220 by a flip chip bonding method. The first semiconductor chip 300 may be arranged such that a front surface, i.e., an active surface on which first chip pads are formed faces the second redistribution wiring layer 220. The first chip pads of the first semiconductor chip 300 may be electrically connected to the second redistribution wirings 222 of the second redistribution wiring layer 220 by first conductive bumps 320. The second semiconductor chip 400a may be arranged such that a front surface, i.e., an active surface on which second chip pads are formed faces the second redistribution wiring layer 220. The second chip pads of the second semiconductor chips 400a may be electrically connected to the second redistribution wirings 222 of the second redistribution wiring layer 220 by second conductive bumps 420a. For example, the first and second conductive bumps 320 and 420a may include micro bumps (uBumps).

For example, a first underfill member may be disposed between the first semiconductor chip 300 and the second redistribution wiring layer 220. A second underfill member may be disposed between the second semiconductor chip 400a and the second redistribution wiring layer 220. The first and second underfill members may include a material having relatively high fluidity to effectively fill small spaces between the first semiconductor chip 300 and the second redistribution wiring layer 220 and between the second semiconductor chip 400a and the second redistribution wiring layer 220. For example, the first and second underfill members may include an adhesive including an epoxy material.

The first semiconductor chip 300 may be a logic chip including a logic circuit. The logic chip may be a controller that controls memory chips. The first semiconductor chip may be a processor chip such as an ASIC serving as a host such as a CPU, GPU, or SOC, or an application processor (AP). The second semiconductor chip 400a may include a memory chip including a memory circuit. For example, the second semiconductor chip 400a may include volatile memory devices such as SRAM devices, DRAM devices, etc., and non-volatile memory device such as flash memory devices, PRAM devices, MRAM devices, RRAM devices, etc.

The numbers, sizes, arrangements, etc. of the first semiconductor chip 300 and the second semiconductor chip 400a are provided as examples, and it will be understood that the present inventive concept is not limited thereto.

In some example embodiments of the present inventive concept, a second sealing member 520 may be formed on the first surface 221a of the second redistribution wiring layer 220 and may cover the first semiconductor chip 300 and the plurality of second semiconductor chips 400a. The second sealing member 520 may be an upper sealing member formed on the upper surface 221a of the second redistribution wiring layer 220. The second sealing member 520 may expose upper surfaces of the first semiconductor chip 300 and the plurality of second semiconductor chips 400a.

For example, the second sealing member 520 may include an epoxy molding compound (EMC). The second sealing member 520 may include, for example, UV resin, polyurethane resin, silicone resin, silica filler, etc.

In some example embodiments of the present inventive concept, the plurality of third semiconductor chips 400b may be spaced apart from each other in the second region R2 and on the second surface 221b of the second redistribution wiring layer 220. The plurality of third semiconductor chips 400b may be spaced apart from each other along a perimeter of the first region R1.

The plurality of third semiconductor chips 400b may be mounted on the second surface 221b of the second redistribution wiring layer 220 by a flip chip bonding method. The third semiconductor chip 400b may be arranged such that a front surface, i.e., an active surface on which third chip pads are formed faces the second redistribution wiring layer 220. The third chip pads of the third semiconductor chips 400b may be electrically connected to the second redistribution wirings 222 of the second redistribution wiring layer 220 by third conductive bumps 420b. For example, the third conductive bumps 420b may include micro bumps (uBumps).

A third underfill member may be disposed between the third semiconductor chip 400b and the second redistribution wiring layer 220. For example, the third underfill member may include an adhesive including an epoxy material.

The third semiconductor chip 400b may include a memory chip of the same type as the second semiconductor chip 400a. For example, the third semiconductor chip 400b may include volatile memory devices such as SRAM devices, DRAM devices, etc., and non-volatile memory devices such as flash memory devices. PRAM devices, MRAM devices, RRAM devices, etc.

The first semiconductor chip 300 may be electrically connected to the plurality of second semiconductor chips 400a and the plurality of third semiconductor chips 400b by the second redistribution wirings 222 of the second redistribution wiring layer 220.

The numbers, sizes, arrangements, etc. of the third semiconductor chips 400b are provided as examples, and it will be understood that the present inventive concept is not limited thereto.

In some example embodiments of the present inventive concept, a first sealing member 510 may be formed on the second surface 221b of the second redistribution wiring layer 220 and may cover the plurality of third semiconductor chips 400b. The first sealing member 510 may be a lower sealing member formed on the lower surface 221b of the second redistribution wiring layer 220.

For example, the first sealing member 510 may include an epoxy molding compound (EMC). The first sealing member 510 may include, for example, UV resin, polyurethane resin, silicone resin, silica filler, etc.

In some example embodiments of the present inventive concept, the plurality of through plugs 610 as a heat transfer medium may be formed on the second surface 221b of the second redistribution wiring layer 220 and the first region R1 to penetrate the first sealing member 510. The through plugs 610 may extend from the first surface 211a of the first redistribution wiring layer 210 to the second surface 221b of the second redistribution wiring layer 220.

The through plugs 610 may be through mold vias (TMVs) formed to extend through the first sealing member 510. An upper end portion of the through plug 610 may be exposed from an upper surface of the first sealing member 510 and may be electrically connected to the second redistribution wiring 222. A lower end portion of the through plug 610 may be exposed from a lower surface of the first sealing member 510 and may be electrically connected to the first redistribution wiring 212.

The through plugs 610 may include a first group of through plugs 612 and a second group of through plugs 614. The first group of through plugs 612 may be electrically connected to the first semiconductor chip 300, and the second group of through plugs 614 may be electrically insulated from the first semiconductor chip 300.

The first redistribution wiring 212 may include a first through via 213 disposed in the first region R1 and connected to the through plug 614. For example, the first through via 213 may include first, second and third lower vias 213a, 213b and 213c stacked on each other in a vertical direction.

The second redistribution wiring 222 may include a second through via 223 connected to the through plug 614 disposed in the first region R1. For example, the second through via 223 may include first, second and third upper vias 223a, 223b and 223c stacked on each other in the vertical direction.

The second group of through plugs 614 may be connected to the first through vias 213 of the first redistribution wiring layer 210 and the second through vias 223 of the second redistribution wiring layer 220. The first chip pads of the first semiconductor chip 300 may be connected to the second through vias 223 of the second redistribution wiring layer 220.

The through plugs 610 may serve as electrical passages for electrically connecting the first semiconductor chip 300, the second semiconductor chips 400a and the third semiconductor chips 400 to an external device. In addition, the through plugs 610 may be arranged in the first region R1 overlapping the first semiconductor chip 300 and may serve as heat dissipation passages through which heat from the first semiconductor chip 300 may be dissipated to the outside. At this time, the through plugs 610 may be disposed on the lower surface 221b opposite to the upper surface 221a of the second redistribution wiring layer 220 on which the first semiconductor chip 300 is mounted, and heat from the front surface of the first semiconductor chip 300 may be dissipated to the outside through the through plugs 610 in a downward direction.

In some example embodiments of the present inventive concept, a heat dissipation plate 720 may be attached to the second sealing member 520 using a thermal interface material (TIM) 710. The heat dissipation plate 720 may be disposed on the upper surfaces of the first semiconductor chip 300 and the plurality of second semiconductor chips 400a exposed by the second sealing member 520. Accordingly, heat from a rear surface of the first semiconductor chip 300 may be dissipated upward through the heat dissipation plate 720 to the outside.

In some example embodiments of the present inventive concept, the interposer 200 may be mounted on a package substrate 100 through solder bumps 250 as conductive connection members. For example, the solder bumps 250 may include C4 bumps or copper-pillar bumps. The first redistribution wirings 212 of the interposer 200 may be electrically connected to substrate pads of the package substrate 100 by the solder bumps 250.

The external connection members 130 for electrical connection with external devices may be disposed on external connection pads on an outer surface of the package substrate 100. For example, the external connection member 130 may be a solder ball. The semiconductor package 10 may be mounted on a module substrate via the solder balls.

As mentioned above, the semiconductor package 10 may include the upper redistribution wiring layer 220, the first semiconductor chip 300, the plurality of second semiconductor chips 400a, the plurality of third semiconductor chips 400b, the lower sealing member 510, the plurality of through plugs 610, and the lower redistribution wiring layer 210. The upper redistribution wiring layer 220 has the upper redistribution wirings 222. The first semiconductor chip 300 may be mounted on the upper surface 221a of the first region R1 of the upper redistribution wiring layer 220. The plurality of second semiconductor chips 400a may be arranged to be spaced apart from each other on the upper surface 221a of the second region R2 of the upper redistribution wiring layer 220. The plurality of third semiconductor chips 400b may be arranged to be spaced apart from each other on the lower surface 221b of the second region R2 of the upper redistribution wiring layer 220. The lower sealing member 510 may be disposed on the lower surface 221b of the upper redistribution wiring layer 220 and may cover the plurality of third semiconductor chips 400b. The plurality of through plugs 610 may be disposed on the lower surface of the first region R1 of the upper redistribution wiring layer 220 and may extend through the lower sealing member 510 to be electrically connected to the upper redistribution wirings 222. The lower redistribution wiring layer 210 may be arranged on the lower surface of the lower sealing member 510 and may have the lower redistribution wirings 212 that are electrically connected to the plurality of through plugs 610.

The first semiconductor chip 300 may be mounted on the second redistribution wiring layer 220 in a face down manner, and the heat generated from the first semiconductor chip 300 may be hardly dissipated through a side surface of the first semiconductor chip 300. Most of the heat may be transferred in a direction substantially perpendicular to the front and rear surfaces of the first semiconductor chip 300.

Because the plurality of second and third semiconductor chips 400a and 400b are not disposed on the front and rear surfaces of the first semiconductor chip 300 but are disposed in the second region R2 that does not overlap the first semiconductor chip 300, the influence of the second and third semiconductor chips 400a and 400b on deteriorating heat dissipation characteristics of the first semiconductor chip 300 may be minimized.

Further, among the heat generated in the first semiconductor chip 300, the heat radiated downward from the front surface of the first semiconductor chip 300 may be dissipated to the outside through the second through vias 223, the through plugs 610 and the first through vias 213. Heat dissipated upward from the rear surface of the first semiconductor chip 300 may be dissipated to the outside through the heat dissipation plate 720.

Accordingly, it may be possible to increase the number of accommodated memory chips and optimize heat dissipation characteristics while maintaining the size of the package.

Hereinafter, a method of manufacturing the semiconductor package of FIG. 1 will be described.

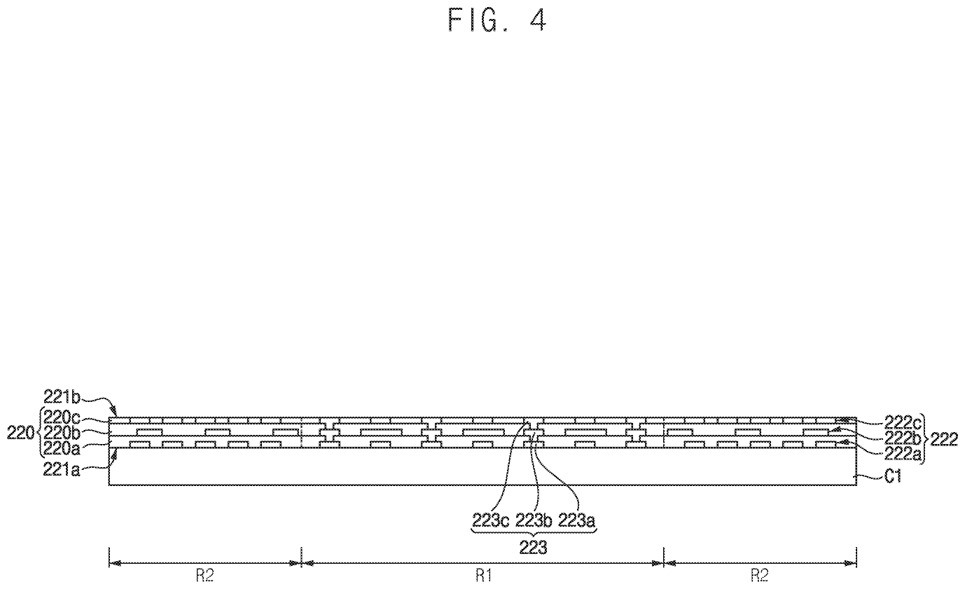

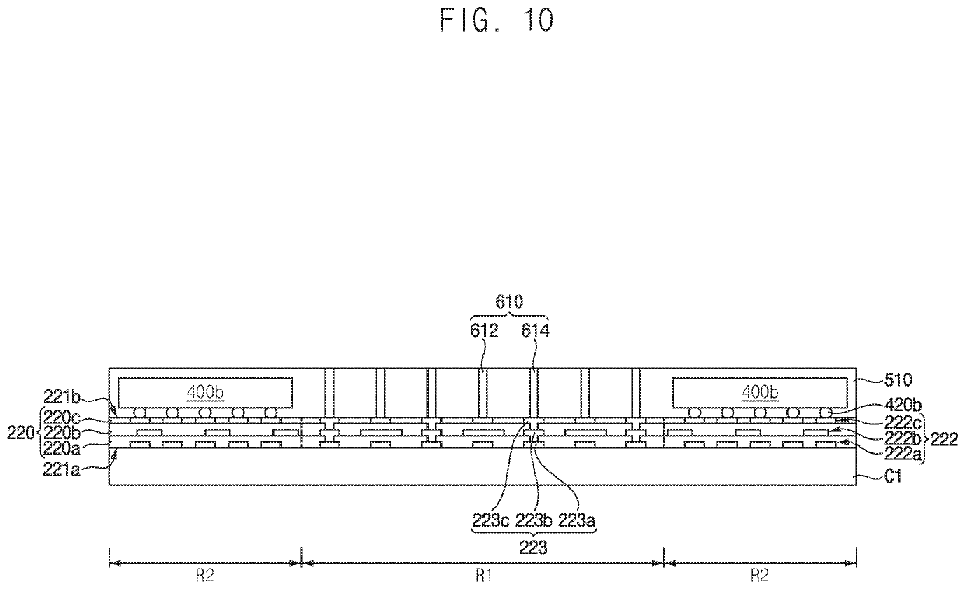

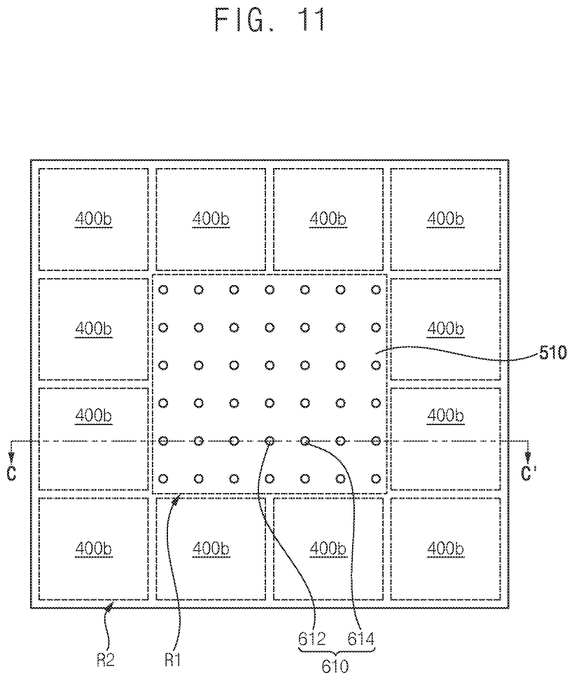

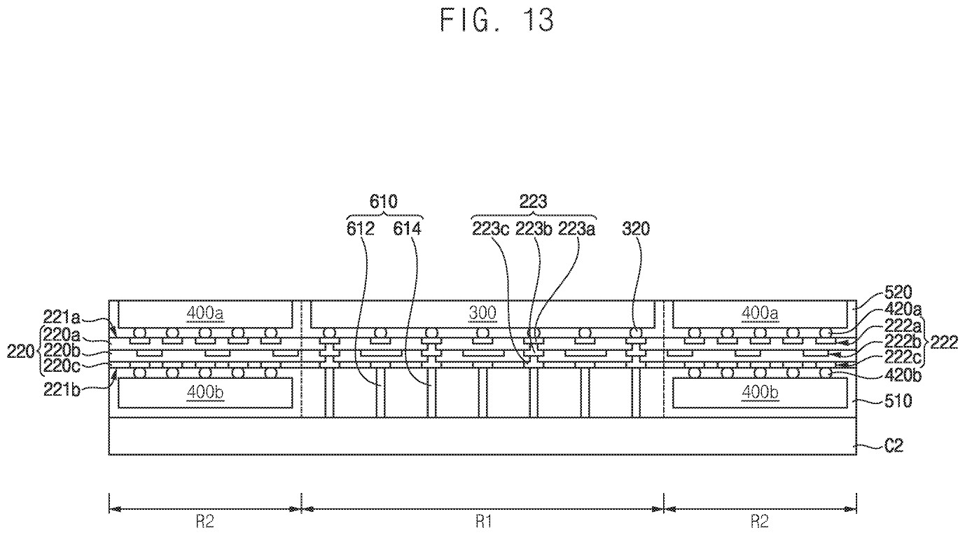

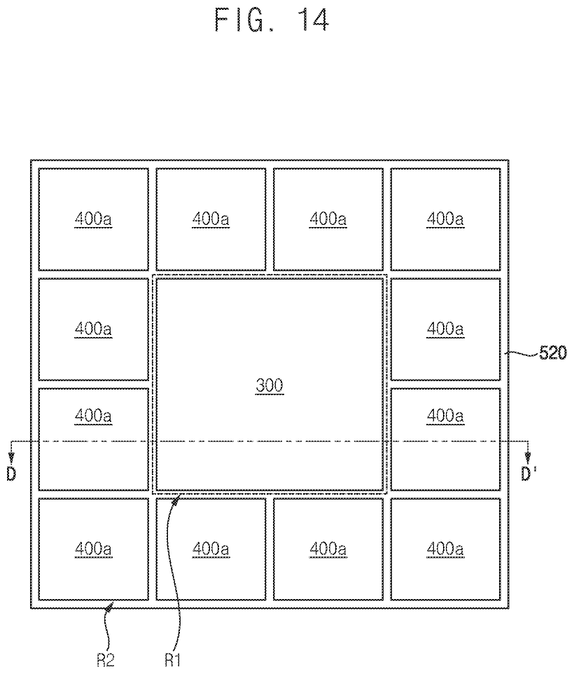

FIGS. 4 to 16 are views illustrating a method of manufacturing a semiconductor package in accordance with an example embodiment of the present inventive concept. FIGS. 4 to 10, 12, 13, 15 and 16 are cross-sectional views illustrating a method of manufacturing a semiconductor package with accordance with an example embodiment of the present inventive concept. FIG. 11 is a plan view of FIG. 10. FIG. 14 is a plan view of FIG. 13. FIG. 10 is a cross-sectional view taken along the line C-C′ in FIG. 11. FIG. 14 is a cross-sectional view taken along the line D-D′ in FIG. 13.

Referring to FIG. 4, a second redistribution wiring layer 220 having second redistribution wirings 222 may be formed on a first carrier substrate C1.

In some example embodiments of the present inventive concept, first upper redistribution wirings 222a may be formed on the first carrier substrate C1 and a first upper insulating layer 220a may be formed on the first carrier substrate C1 to cover the first upper redistribution wirings 222a.

For example, the first upper redistribution wirings 222a may be formed by an electrolytic plating process. After a seed layer is formed on the first carrier substrate C1, the seed layer may be patterned and an electroplating process may be performed to form the first upper redistribution wirings. The first upper redistribution wiring 222a may include, for example, aluminum (Al), copper (Cu), tin (Sn), nickel (Ni), gold (Au), platinum (Pt), or an alloy thereof.

After bonding pads for bonding with conductive bumps are forming on the first carrier substrate C1, the first upper redistribution wirings 222a may be formed on the bonding pads. In addition, as will be described later, prior to mounting a first semiconductor chip and a plurality of second semiconductor chips on the second redistribution wiring layer 220, bonding pads such as UBM may be formed on redistribution wiring pad portions of the first upper redistribution wirings 222a.

The first upper insulating layer 220a may include a polymer or a dielectric layer. For example, the first upper insulating layer 220a may include polyimide (PI), lead oxide (PbO), polyhydroxystyrene (PHS), or NOVOLAC. The first upper insulating layer 220a may be formed by a vapor deposition process, a spin coating process, etc.

Then, after the first upper insulating layer 220a is patterned to form openings that expose the first upper redistribution wirings 222a, second upper redistribution wirings 222b may be formed on the first upper insulating layer 220a to be electrically connected to the first upper redistribution wirings 222a through the openings of the first upper insulating layer 220a respectively.

For example, the second upper redistribution wiring 222b may be formed by forming a seed layer on a portion of the first upper insulating layer 220a and in the opening, patterning the seed layer and performing an electroplating process. Accordingly, at least a portion of the second upper redistribution wiring 222b may contact the first upper redistribution wiring 222a through the opening. For example, at least a portion of the second upper redistribution wiring 222b may directly contact the first upper redistribution wiring 222a through the opening.

Similarly, after a second upper insulating layer 220b is formed on the first upper insulating layer 220a to cover the second upper redistribution wirings 222b, the second upper insulating layer 220b may be patterned to form openings that expose the second upper redistribution wirings 222b. Then, third upper redistribution wirings 222c may be formed on the second upper insulating layer 220b to be electrically connected to the second upper redistribution wirings 222b through the openings of the second upper insulating layer 220b.

Then, after a third upper insulating layer 220c is formed on the second upper insulating layer 220b to cover the third upper redistribution wirings 222c, the third upper insulating layer 220c may be patterned to form openings that expose the third upper redistribution wirings 222c. The third upper redistribution wirings 222c may be outermost redistribution wirings exposed by the openings of the third upper redistribution wirings 222c. A portion of the outermost redistribution wiring may include a redistribution wiring pad portion. For example, a bump pad such as a UBM may be formed on the redistribution wiring pad portion.

Thus, the second redistribution wiring layer 220 having the second redistribution wirings 222 as an organic interposer or a redistribution wiring interposer may be formed on the first carrier substrate C1. The second redistribution wiring layer 220 may include the stacked first, second and third upper insulating layers 220a, 220b and 220c and the second redistribution wirings 222 in the stacked first, second and third upper insulating layers 220a, 220b and 220c. The second redistribution wiring 222 may include the first, second and third upper redistribution wirings 222a, 222b and 222c.

The second redistribution wiring layer 220 may have a first surface 221a and a second surface 221b opposite to the first surface 221a. The second redistribution wiring layer 220 may include a first region R1 positioned in the central region of the second redistribution wiring 220 and a second region R2 at least partially surrounding the first region R1. As will be described later, when viewed from a plan view, the first region R1 may be a region that overlaps the first semiconductor chip mounted on the first surface 221a of the second redistribution wiring layer 220, and the second region R2 may be a region that overlaps a plurality of second semiconductor chips mounted on the first surface 221a of the second redistribution wiring layer 220 and a plurality of third semiconductor chips mounted on the second surface 221b of the second redistribution wiring layer 220.

The second redistribution wiring 222 may include a second through via 223 that is disposed in the first region R1 and is connected to a through plug as described later. For example, the second through via 223 may include first, second and third upper vias 223a, 223b and 223c stacked on each other in a vertical direction.

The numbers, sizes, arrangements, etc. of the upper insulating layers 220a, 220b and 220c and the upper redistribution wirings 222a, 222b and 222c of the second redistribution wiring layer 220 are provided as examples, and it will be understood that the present inventive concept is not limited thereto.

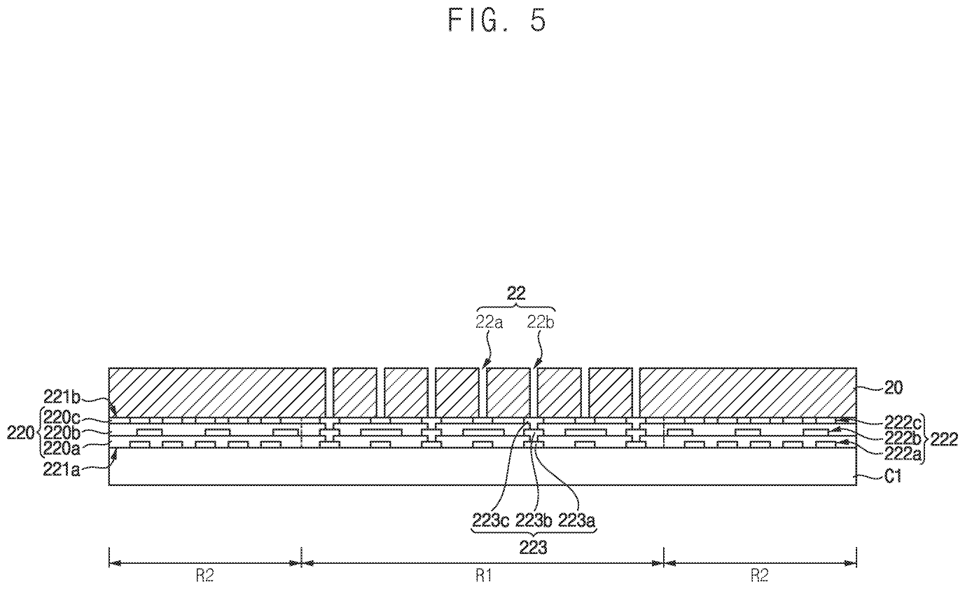

Referring to FIGS. 5 to 7, a plurality of through plugs 610 as a heat transfer medium may be formed in the first region R1 on the second surface 221b of the second redistribution wiring layer 220.

As illustrated in FIG. 5, a photoresist layer may be formed on the second surface 221b of the second redistribution wiring layer 220, and an exposure process may be performed on the photoresist layer to form a photoresist pattern 20 having openings 22 for forming a plurality of through plugs disposed on the second surface 221b of the first region R of the second redistribution wiring layer 220.

The openings 22 may include first openings 22a for forming a first group of through plugs and second openings 22b for forming a second group of through plugs. The first opening 22a may expose at least a portion of the third upper redistribution wiring 222c in the first region R1. The second opening 22b may expose at least a portion of the third upper via 223c of the second through via 223 in the first region R1. When a bump pad such as UBM is formed on the redistribution wiring pad portion of the third upper redistribution wiring 222c, the opening may expose at least a portion of the bump pad.

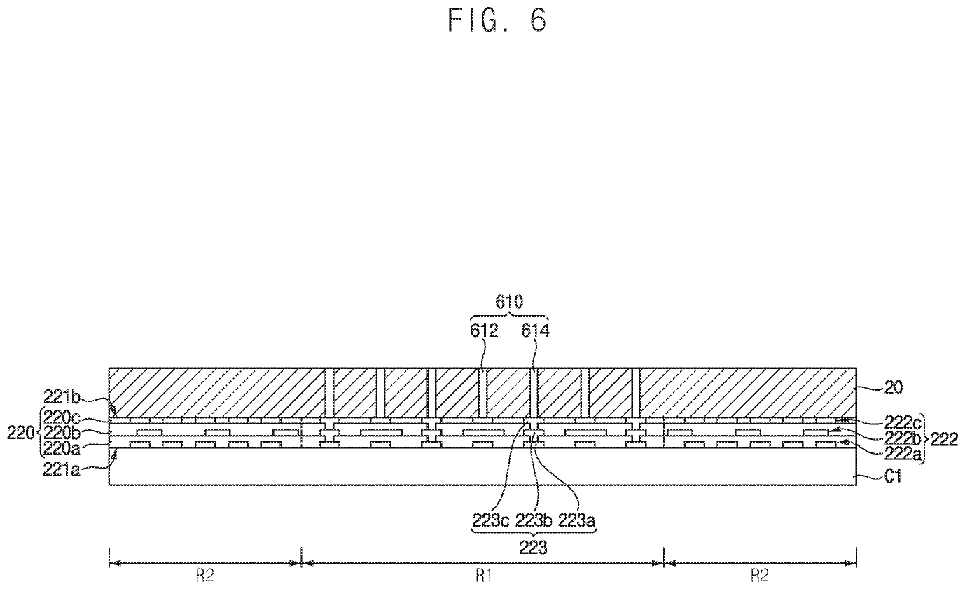

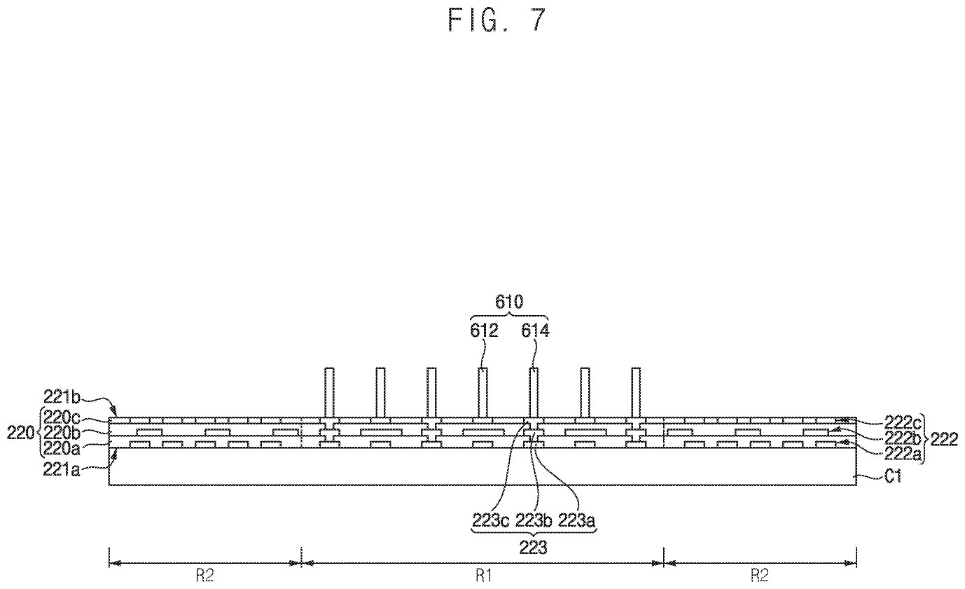

Then, as illustrated in FIGS. 6 and 7, the openings 22 of the first photoresist pattern 20 may be filled up with a conductive material by an electrolytic plating process to form through plugs 610. Then, the first photoresist pattern 20 may be removed by a strip process.

The through plugs 610 may include a first group of through plugs 612 and a second group of through plugs 614. The first group of the through plugs 612 may be connected to the second redistribution wirings 222, and the second group of the through plugs 614 may be connected to the second through vias 223.

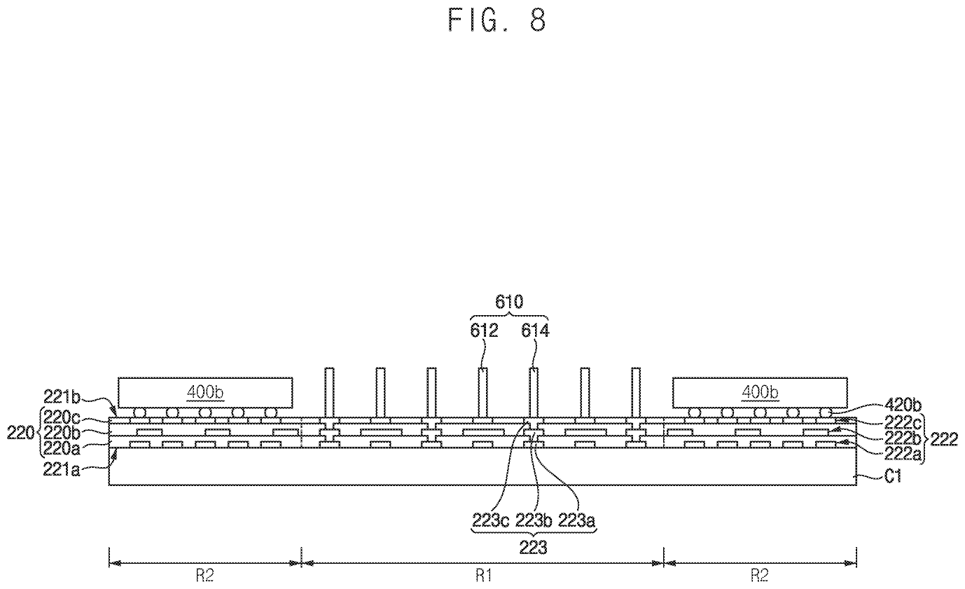

Referring to FIG. 8, a plurality of third semiconductor chips 400b may be mounted in the second region R2 on the second surface 221b of the second redistribution wiring layer 220.

In some example embodiments of the present inventive concept, the plurality of third semiconductor chips 400b may be spaced apart from each other in the second region R2 on the second surface 221b of the second redistribution wiring layer 220. The plurality of third semiconductor chips 400b may be spaced apart from each other along a perimeter of the first region R1.

The plurality of third semiconductor chips 400b may be mounted on the second surface 221b of the second redistribution wiring layer 220 by a flip chip bonding method. The third semiconductor chip 400b may be arranged such that a front surface, i.e., an active surface on which third chip pads are formed faces the second redistribution wiring layer 220. The third chip pads of the third semiconductor chips 400b may be electrically connected to the second redistribution wirings 222 of the second redistribution wiring layer 220 by third conductive bumps 420b. For example, the third conductive bumps 420b may include micro bumps (uBumps).

For example, a third underfill member may be disposed between the third semiconductor chip 400b and the second redistribution wiring layer 220. The third underfill member may include a material having relatively high fluidity to effectively fill a space between the third semiconductor chip 400b and the second redistribution wiring layer 220. For example, the third underfill member may include an adhesive including an epoxy material.

The third semiconductor chip 400b may include a memory chip including a memory circuit. For example, the third semiconductor chip 400b may include volatile memory devices such as SRAM devices. DRAM devices, etc., and non-volatile memory device such as flash memory devices, PRAM devices, MRAM devices, RRAM devices, etc.

For example, a height of the third semiconductor chip 400b from the second surface 211b of the second redistribution wiring layer 220 may be less than a height of the through plug 610 from the second surface 21l b of the second redistribution wiring layer 220.

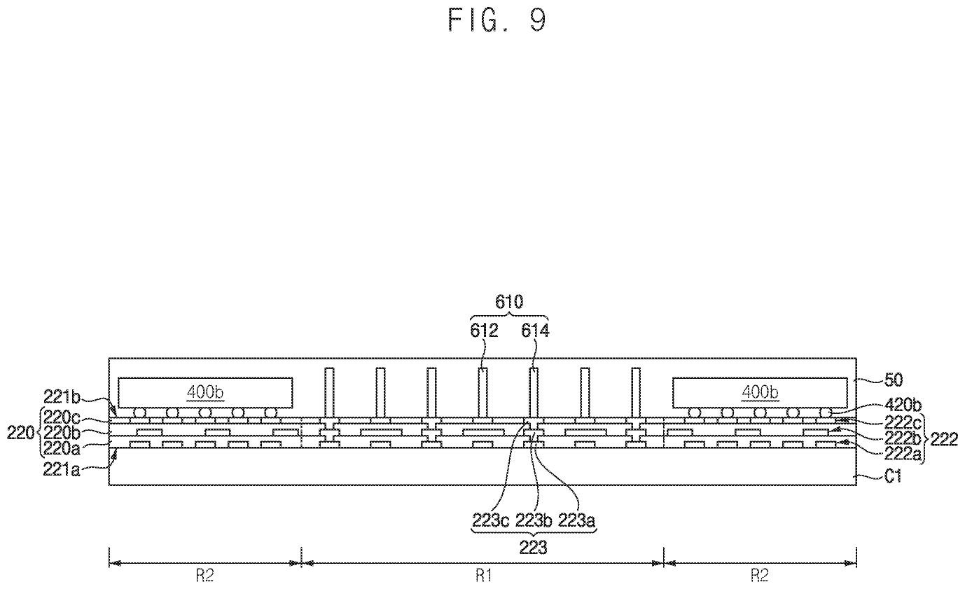

Referring to FIGS. 9 to 11, a first sealing member 510 may be formed on the second surface 221b of the second redistribution wiring layer 220 to cover the plurality of third semiconductor chips 400b and the plurality of through plugs 610. The first sealing member 510 may be a lower sealing member formed on the lower surface 221b of the second redistribution wiring layer 220.

As illustrated in FIG. 9, a sealing material 50 may be formed on the second surface 221b of the second redistribution wiring layer 220 to cover the plurality of third semiconductor chips 400b and the plurality of through plugs 610. The sealing material 50 may be formed to cover upper surfaces of the third semiconductor chips 400b and upper surfaces of the plurality of through plugs 610. For example, the sealing material 50 may include an epoxy molding compound (EMC). The sealing material 50 may include, for example, UV resin, polyurethane resin, silicone resin, silica filler, etc.

As illustrated in FIGS. 10 and 11, an upper portion of the sealing material 50 may be partially removed to from the first sealing member 510 that exposes the upper surfaces of the plurality of through plugs 610. Thus, the plurality of through plugs 610 may be formed on the second surface 221b of the first region R1 of the second redistribution wiring layer 220 to penetrate the first sealing member 510.

One end portion (lower surface) of the through plug 610 may be exposed from one surface of the first sealing member 510 and may be electrically connected to the second redistribution wiring 222. The other end portion (upper surface) of the through plug 610 may be exposed to the outside from the other surface of the first sealing member 510. The through plugs 610 may be through mold vias (TMVs) formed to extend through the first sealing member 510.

The through plugs 610 may include the first group of through plugs 612 and the second group of through plugs 614. As will be described later, the first group of through plugs 612 may be electrically connected to the first semiconductor chip, and the second group of through plugs 614 may be electrically insulated from the first semiconductor chip. The second group of through plugs 614 may be connected to the second through vias 223 of the second redistribution wiring layer 220.

The through plugs 610 may serve as electrical passages for electrically connecting the first semiconductor chip, the second semiconductor chips, and the third semiconductor chips to an external device. In addition, the through plugs 610 may be disposed in the first region R1 overlapping the first semiconductor chip to serve as heat dissipation passages through which heat from the first semiconductor chip is discharged to the outside. At this time, the through plugs 610 may be disposed on the second surface 221b opposite to the first surface 221a of the second redistribution wiring layer 220 on which the first semiconductor chip is mounted, and heat from the front surface of the first semiconductor chip may be dissipated to the outside through the second through vias 223 and through plugs 610.

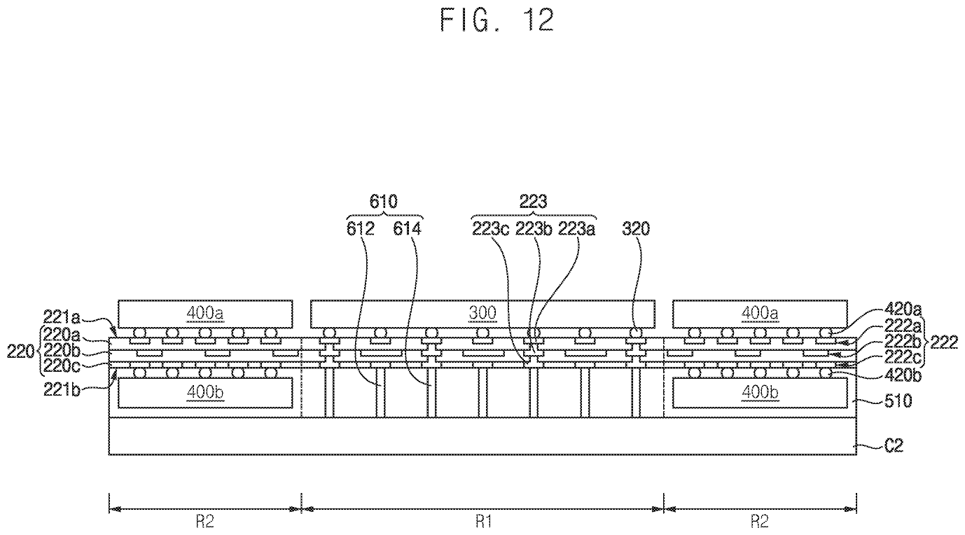

Referring to FIG. 12, the first carrier substrate C1 mat be removed, the structure of FIG. 10 may be turned over, and the first sealing member 510 may be attached on a second carrier substrate C2. Then, a first semiconductor chip 300 and a plurality of second semiconductor chips 400a may be mounted on the first surface 221a of the second redistribution wiring layer 220.

In some example embodiments of the present inventive concept, the first semiconductor chip 300 may be arranged in the first region R1 on the first surface 221a of the second redistribution wiring layer 220, and the plurality of second semiconductor chips 400a may be spaced apart from each other within the second region R2 on the first surface 221a of the second redistribution wiring layer 220. The plurality of second semiconductor chips 400a may be spaced apart from each other along a perimeter of the first semiconductor chip 300.

The first semiconductor chip 300 and the plurality of second semiconductor chips 400a may be mounted on the first surface 221a of the second redistribution wiring layer 220 by a flip chip bonding method. The first semiconductor chip 300 may be arranged such that a front surface, i.e., an active surface on which first chip pads are formed faces the second redistribution wiring layer 220. The first chip pads of the first semiconductor chip 300 may be electrically connected to the second redistribution wirings 222 of the second redistribution wiring layer 220 through first conductive bumps 320. The second semiconductor chip 400a may be arranged such that a front surface, i.e., an active surface on which second chip pads are formed faces the second redistribution wiring layer 220. The second chip pads of the second semiconductor chips 400a may be electrically connected to the second redistribution wirings 222 of the second redistribution wiring layer 220 by second conductive bumps 420a. For example, the first and second conductive bumps 320 and 420a may include micro bumps (uBumps).

For example, a first underfill member may be disposed between the first semiconductor chip 300 and the second redistribution wiring layer 220. A second underfill member may underfill between the second semiconductor chip 400a and the second redistribution wiring layer 220. For example, the first and second underfill members may include an adhesive including an epoxy material.

The first semiconductor chip 300 may be a logic chip including a logic circuit. The logic chip may be a controller that controls memory chips. The first semiconductor chip 300 may be a processor chip such as an ASIC serving as a host such as a CPU, GPU, or SOC, or an application processor (AP). The second semiconductor chip 400a may include a memory chip of the same type as the third semiconductor chip 400b. For example, the second semiconductor chip 400a may include volatile memory devices such as SRAM devices, DRAM devices, etc., and non-volatile memory devices such as flash memory devices, PRAM devices, MRAM devices, RRAM devices, etc.

The first semiconductor chip 300 may be electrically connected to the plurality of second semiconductor chips 400a and the plurality of third semiconductor chips 400b by the second redistribution wirings 222 of the second redistribution wiring layer 220. The first chip pads of the first semiconductor chip 300 may be connected to the second through vias 223 of the second redistribution wiring layer 220.

The numbers, sizes, arrangements, etc. of the first semiconductor chip 300 and the second semiconductor chip 400a are provided as examples, and it will be understood that the present inventive concept is not limited thereto.

Referring to FIGS. 13 and 14, a second sealing member 520 may be formed on the first surface 221a of the second redistribution wiring layer 220 to cover the first semiconductor chip 300 and the plurality of second semiconductor chips 400a. The second sealing member 520 may be an upper sealing member formed on the upper surface 221a of the second redistribution wiring layer 220.

For example, the second sealing member 520 may include an epoxy molding compound (EMC). The second sealing member 520 may include, for example. UV resin, polyurethane resin, silicone resin, silica filler, etc.

In some example embodiments of the present inventive concept, a sealing material may be formed on the first surface 221a of the second redistribution wiring layer 220 to cover upper surfaces of the first semiconductor chip 300 and the plurality of second semiconductor chips 400a. Then, an upper portion of the sealing material may be partially removed until upper surfaces the first semiconductor chip 300 and the plurality of second semiconductor chips 400a are exposed.

Thus, the second sealing member 520 may expose the upper surfaces of the first semiconductor chip 300 and the plurality of second semiconductor chips 400a.

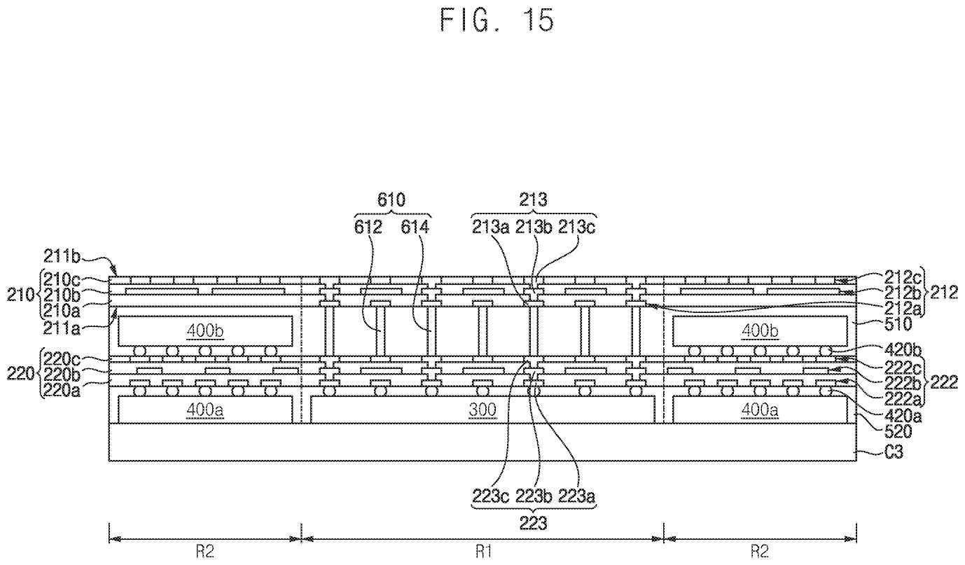

Referring to FIG. 15, the second carrier substrate C2 may be removed, the structure of FIG. 13 may be turned over, the second sealing member 520 may be attached on the third carrier substrate C3. Then, a first redistribution wiring layer 210 having first redistribution wirings 212 may be formed the first sealing member 510. The first redistribution wirings 212 may be electrically connected to the through plugs 610.

In some example embodiments of the present inventive concept, first lower redistribution wirings 212a may be formed on end portions of the through plugs 610, which are exposed from the first sealing member 510, and a first lower insulating layer 210a may be formed on the first sealing member 510 to cover the first lower redistribution wirings 212a.

For example, after forming a seed layer on the first sealing member 510, the seed layer may be patterned and an electroplating process may be performed to form the first lower redistribution wirings 212a. The first lower redistribution wiring 212 may include, for example, aluminum (Al), copper (Cu), tin (Sn), nickel (Ni), gold (Au), platinum (Pt), or an alloy thereof.

The first lower insulating layer 210a may include a polymer or a dielectric layer. For example, the first lower insulating layer 210a may include polyimide (PI), lead oxide (PbO), polyhydroxystyrene (PHS), or NOVOLAC. The first lower insulating layer 210a may be formed by a vapor deposition process, a spin coating process, etc.

Then, the first lower insulating layer 210a may be patterned to form openings that exposes the first lower redistribution wirings 212a, and second lower redistribution wirings 212b may be formed on the first lower insulating layer 210a to be electrically connected to the first lower redistribution wirings 212a through the openings.

For example, a seed layer may be formed on a portion of the first lower insulating layer 210a and in the opening, the seed layer may be patterned and then an electroplating process may be performed to form the second lower redistribution wiring 212b. Accordingly, at least a portion of the second lower redistribution wiring 212b may contact the first lower redistribution wiring 212a through the opening. For example, at least a portion of the second lower redistribution wiring 212b may directly contact the first lower redistribution wiring 212a through the opening.

Similarly, after a second lower insulating layer 210b is formed on the first lower insulating layer 210a to cover the second lower redistribution wirings 212b, the second lower insulating layer 210b may be patterned to form openings that expose the second lower redistribution wirings 212b. Then, third lower redistribution wirings 212c may be formed on the second lower insulating layer 210b to be electrically connected to the second lower redistribution wirings 212b through the openings.

Then, after forming a third lower insulating layer 210c on the second lower insulating layer 210b to cover the third lower redistribution wirings 212c, the third lower insulating layer 210c may be patterned to form openings that expose the third lower redistribution wirings 212c. The third lower redistribution wirings 212c exposed by the openings may be outermost redistribution wirings. A portion of the outermost redistribution wiring may include a redistribution wiring pad portion. For example, a bump pad such as a UBM may be formed on the redistribution wiring pad portion.

Thus, the first redistribution wiring layer 210 having the first redistribution wirings 212 as an organic interposer or a redistribution wiring interposer may be formed on the first sealing member 510. The first redistribution wiring layer 210 may include the stacked first, second and third lower insulating layers 210a. 210b and 210c and the first redistribution wirings 212 in the stacked first, second and third lower insulating layers 210a, 210b and 210c. The first redistribution wirings 212 may include the first, second and third lower redistribution wirings 212a. 212b and 212c.

The first redistribution wiring layer 210 may have a first surface 211a and a second surface 211b opposite to the first surface 211a. The first redistribution wiring layer 210 may include a first region R1 disposed in the central region of the first redistribution wiring layer 210 and a second region R2 surrounding the first region R1. The first redistribution wiring 212 may include a first through via 213 disposed in the first region R1 and connected to the through plug 614. For example, the first through via 213 may include first, second and third lower vias 213a, 213b and 213c stacked on one another in a vertical direction.

The numbers, sizes, arrangements, etc. of the lower insulating layers 210a. 210b and 210c and the lower redistribution wirings 212a. 212b and 212c of the first redistribution wiring layer 210 are provided as examples, and it will be appreciated that the present inventive concept is not limited thereto.

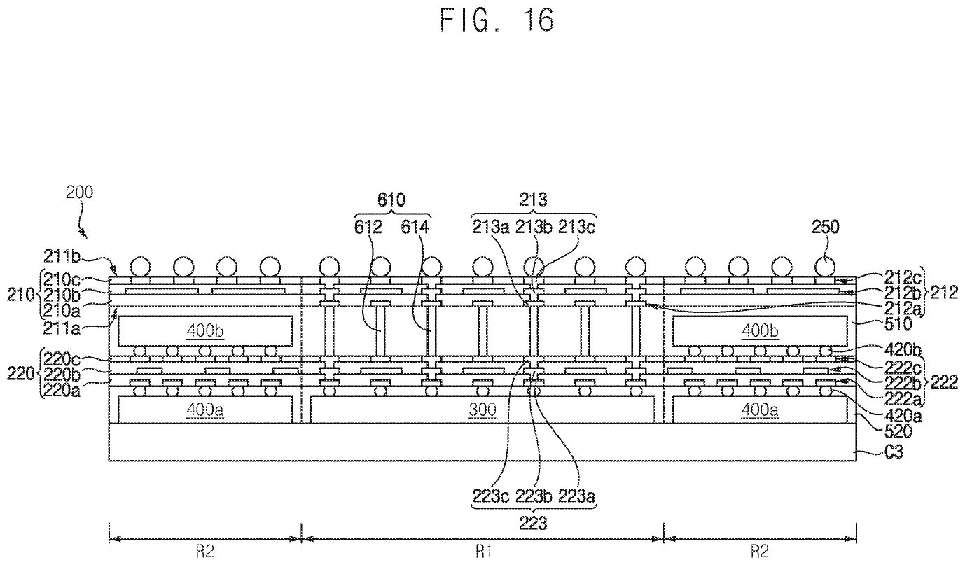

Referring to FIG. 16, conductive connection members 250 may be formed on the second surface 211b of the first redistribution wiring layer 210. The conductive connection members 250 may be electrically connected to the first redistribution wirings 212. The conductive connection members 250 may be respectively disposed on the third lower redistribution wirings 212c as the outermost redistribution wirings.

The conductive connection members 250 may be arranged in an array form across the first region R1 and the second region R2 of the first redistribution wiring layer 210. For example, the conductive connection members 250 may include solder bumps. The solder bumps may include C4 bumps or copper-pillar bumps.

Accordingly, the conductive connecting members 250 may be formed on a lower surface of an interposer 200 having the first and second wiring layers 210 and 220.

Then, the interposer 200 may be mounted on a package substrate 100 via the solder bumps 250 serving as the conductive connection members. Then, external connection members such as solder balls may be disposed on external connection pads on a lower surface of the package substrate 100 to form the semiconductor package 10 of FIG. 1.

In addition, a heat dissipation plate 720 (see FIG. 1) may be attached to the second sealing member 520 using a thermal interface material (TIM) 710 (see FIG. 1). The heat dissipation plate 720 may be disposed on the upper surfaces of the first semiconductor chip 300 and the plurality of second semiconductor chips 400a that are exposed by the second sealing member 520. Accordingly, heat from a rear surface of the first semiconductor chip 300 may be dissipated to the outside through the heat dissipation plate 720.

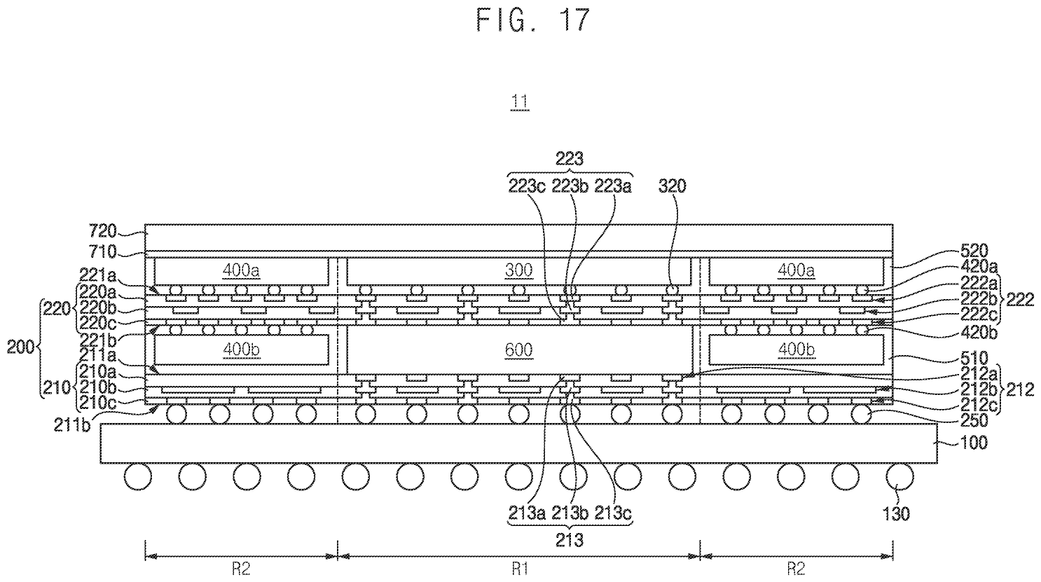

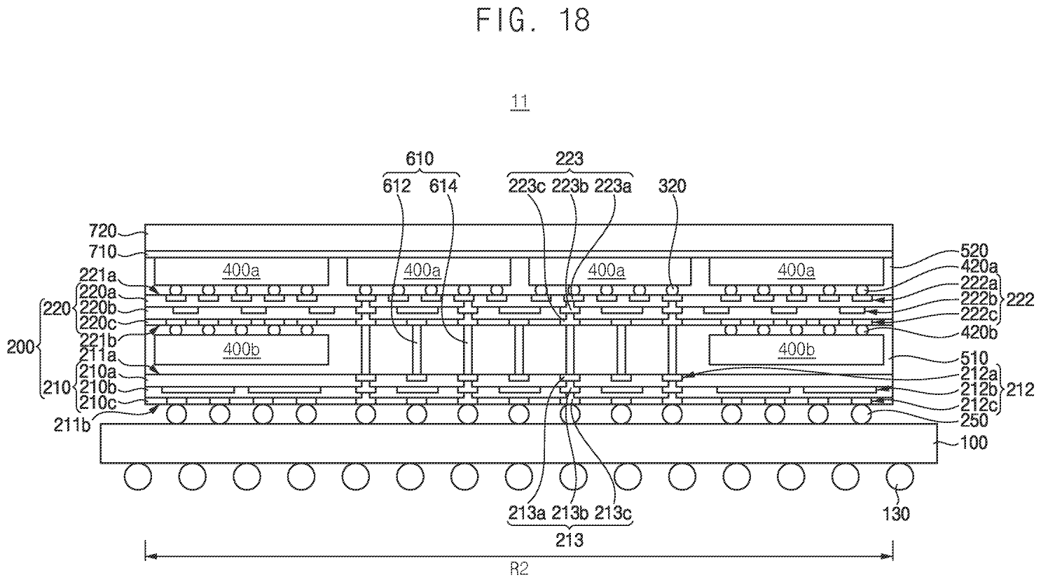

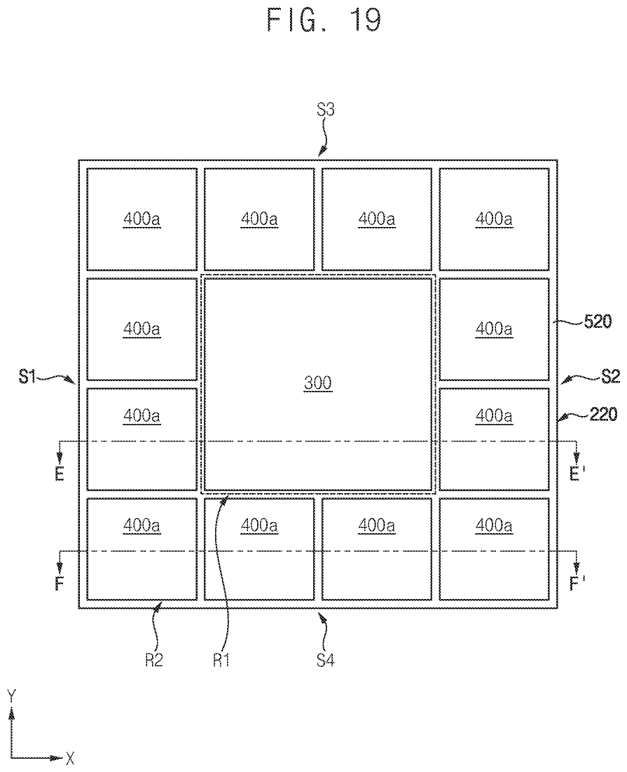

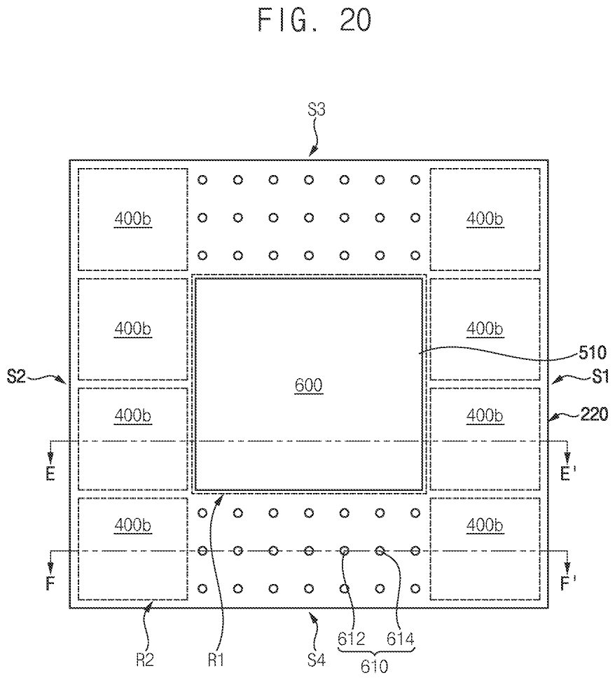

FIG. 17 is a cross-sectional view illustrating a semiconductor package in accordance with an example embodiment of the present inventive concept. FIG. 18 is a cross-sectional view illustrating the semiconductor package in FIG. 17. FIG. 19 is a plan view illustrating a first semiconductor chip and a plurality of second semiconductor chips disposed on an upper surface of a second redistribution wiring layer of FIGS. 17 and 18. FIG. 20 is a plan view illustrating a plurality of third semiconductor chips, a plurality of heat transfer plugs and a heat transfer dummy chip disposed on a lower surface of the second redistribution wiring layer of FIGS. 17 and 18. FIG. 17 is a cross-sectional view taken along the line E-E′ in FIGS. 19 and 20. FIG. 18 is a cross-sectional view taken along the line F-F′ in FIGS. 19 and 20. The semiconductor package may be substantially the same as the semiconductor package described with reference to FIGS. 1 to 3 except for an additional configuration of a heat transfer dummy chip and arrangements of heat transfer plugs. Thus, same reference numerals may be used to refer to the same or like elements throughout the specification and any further repetitive explanation concerning the above elements may be omitted or briefly discussed.

Referring to FIGS. 17 to 20, an interposer 200 of a semiconductor package 11 may include a first redistribution wiring layer 210, a second redistribution wiring layer 220, which is stacked on the first redistribution wiring layer 210, a first semiconductor chip 300 and a plurality of second semiconductor chips 400a, which are disposed on the second redistribution wiring layer 220, a plurality of third semiconductor chips 400b, a heat transfer dummy chip 600, and a plurality of through plugs as heat transfer plugs 610 disposed between the first redistribution wiring layer 210 and the second redistribution wiring layer 220.

In some example embodiments of the present inventive concept, the first semiconductor chip 300 may be disposed in a first region R1 on a first surface 221a of the second redistribution wiring layer 220, and the plurality of second semiconductor chips 400a may be spaced apart from each other within a second region R2 on the first surface 221a of the second redistribution wiring layer 220. The plurality of second semiconductor chips 400a may be spaced apart from each other along a perimeter of the first semiconductor chip 300.

The plurality of third semiconductor chips 400b may be spaced apart from each other in the second region R2 and on a second surface 221b of the second redistribution wiring layer 220. The plurality of third semiconductor chips 400b may be spaced apart from each other in both sides of the first region R1.

In some example embodiments of the present inventive concept, the heat transfer dummy chip 600 as a heat transfer medium may be disposed in the first region R1 and on the second surface 221b of the second redistribution wiring layer 220. The heat transfer dummy chip 600 may be disposed to overlap the first semiconductor chip 300 with the second redistribution wiring layer 220 interposed between the first semiconductor chip 300 and the heat transfer dummy chip 600. An upper surface of the heat transfer dummy chip 6(x) may be in thermal contact with the second surface 221b of the second redistribution wiring layer 220, and a lower surface of the heat transfer dummy chip 600 may be in thermal contact with a first surface 211a of the first redistribution wiring layer 210. For example, the heat transfer dummy chip 600 may be attached on the second surface 221b of the second redistribution wiring layer 220 and the first surface 211a of the first redistribution wiring layer 210 via a thermal interface material layer.

The teat transfer plugs 610 serving as a heat transfer medium may be disposed in the second region R2 and on the second surface 221b of the second redistribution wiring layer 220. The heat transfer plugs 610 may be disposed in both sides of the heat transfer dummy chip 600. The third semiconductor chips 400b may be respectively disposed in both sides of the heat transfer dummy chip 600.

In some example embodiments of the present inventive concept, a first sealing member 510 may be provided on the second surface 221b of the second redistribution wiring layer 220 to cover the plurality of third semiconductor chips 400b, the heat transfer dummy chip 600 and the plurality of through plugs 610. The first sealing member 510 may expose an upper surface of the heat transfer dummy chip 600 and end portions of the plurality of through plugs 610. The through plugs 610 may be through mold vias (TMVs) formed to extend through the first sealing member 510.

As mentioned above, the heat transfer dummy chip 600 may be disposed in the first region R1 overlapping the first semiconductor chip 300 and may serve as a heat dissipation passage for dissipating heat from the front surface of the first semiconductor chip 300 downward to the outside.

The through plugs 610 may be disposed in the second region R2 overlapping at least some of the second semiconductor chips 400a to serve as heat dissipation passages for discharging heat from the front surfaces of at least some of the second semiconductor chips 400a downward to the outside. Additionally, the through plugs 610 may serve as electrical passages for electrically connecting the first semiconductor chip 300, the second semiconductor chips 400a and the third semiconductor chips 400b to an external device.

Hereinafter, a method of manufacturing the semiconductor package of FIGS. 17 and 18 will be described.

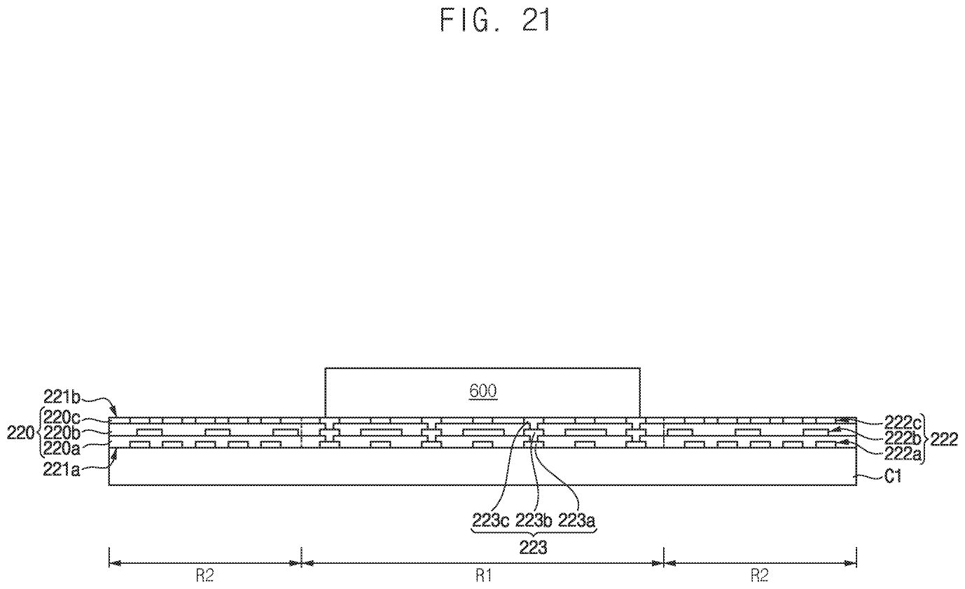

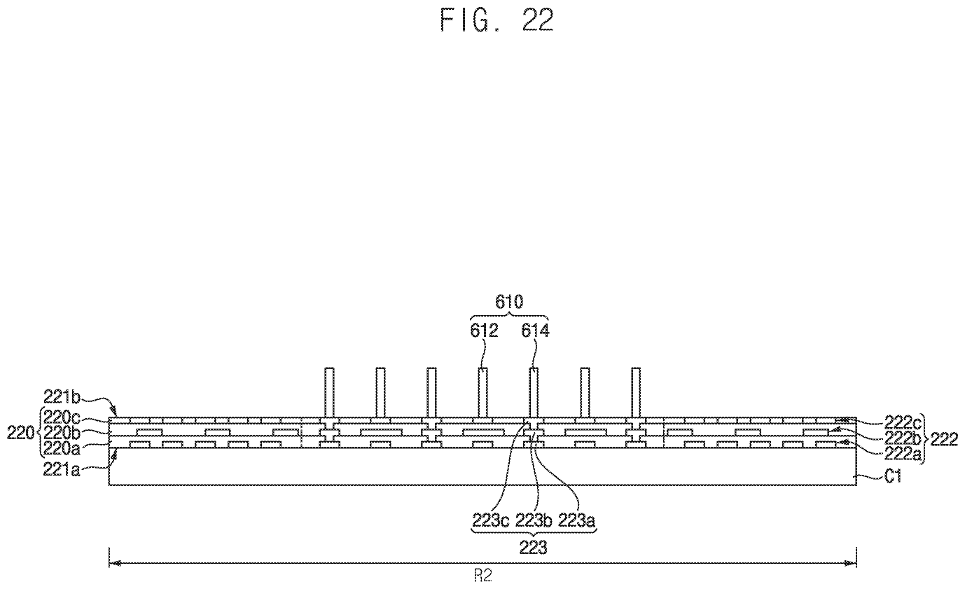

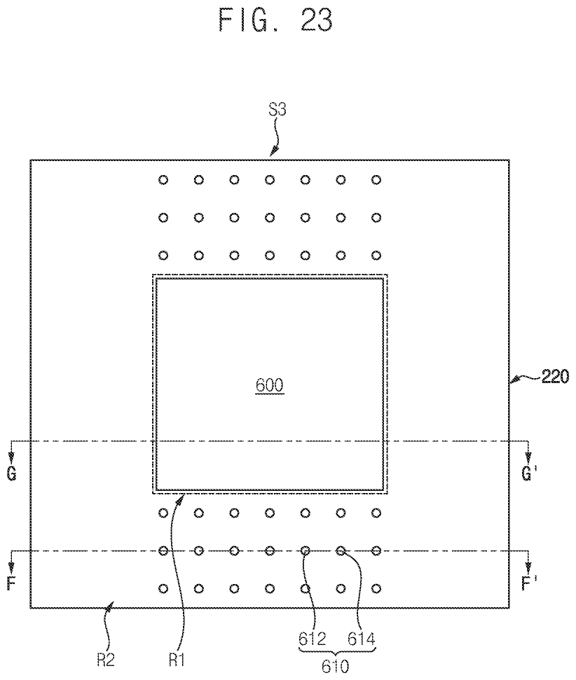

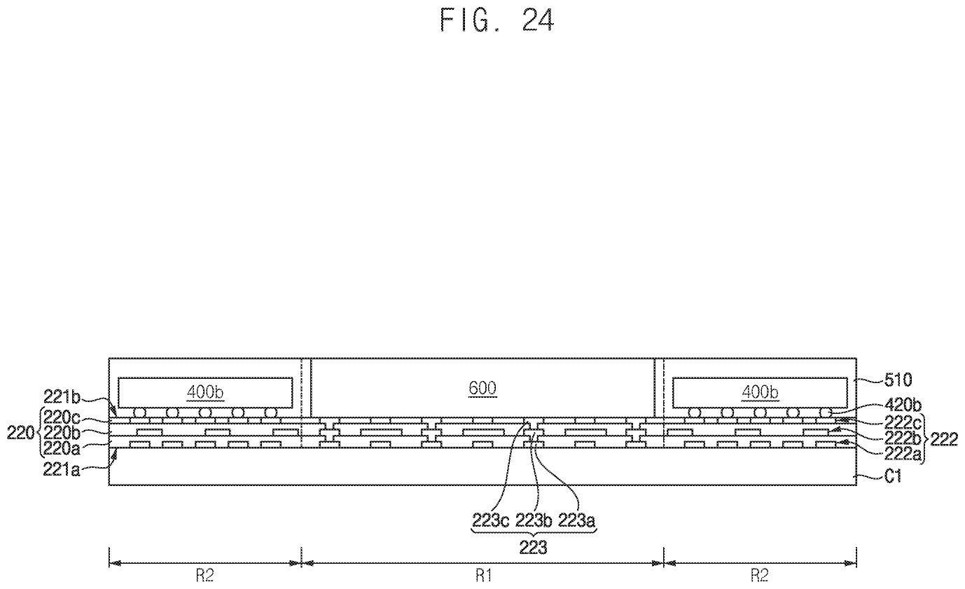

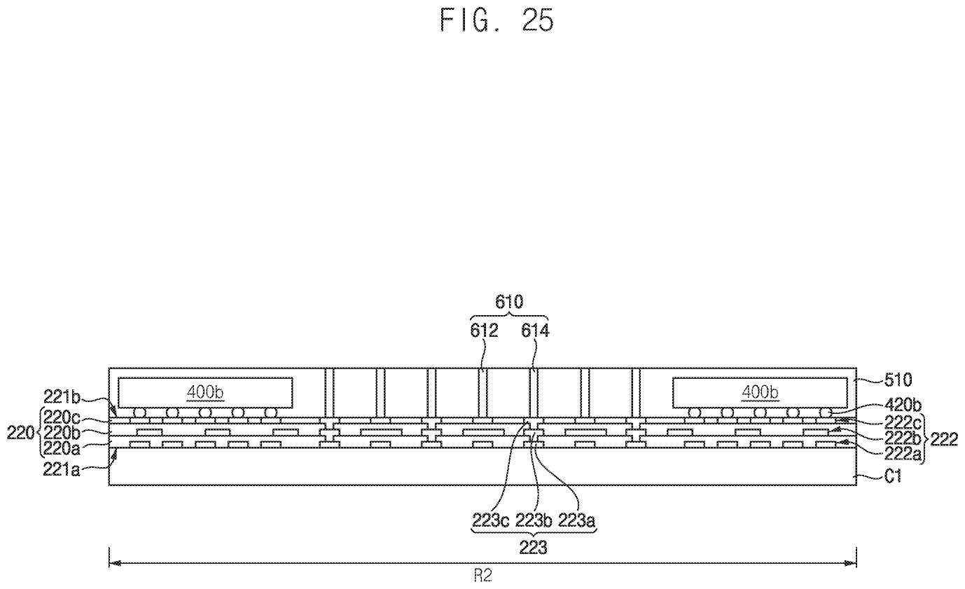

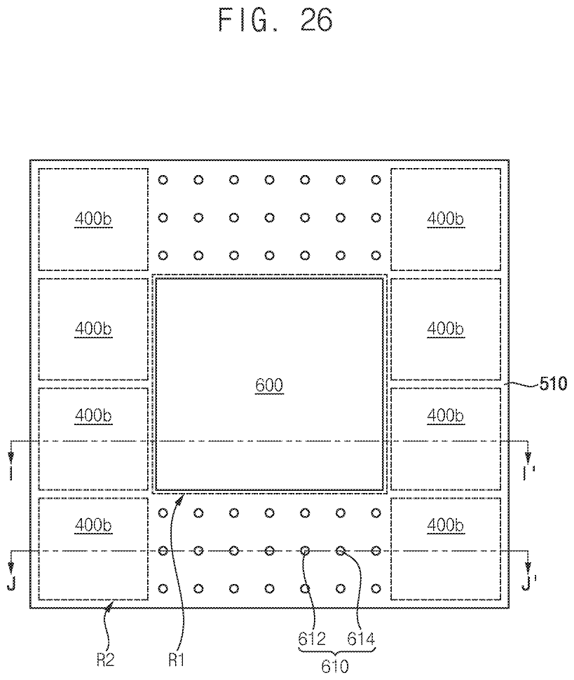

FIGS. 21 to 26 are views illustrating a method of manufacturing a semiconductor package in accordance with an example embodiment of the present inventive concept. FIGS. 21, 22, 24 and 25 are cross-sectional views illustrating a method of manufacturing a semiconductor package in accordance with an example embodiment of the present inventive concept. FIG. 23 is a plan view illustrating a second redistribution wiring layer in FIGS. 21 and 22. FIG. 26 is a plan view illustrating the second redistribution wiring layer in FIGS. 24 and 25. FIG. 21 is a cross-sectional view taken along the line G-G′ in FIG. 23. FIG. 22 is a cross-sectional view taken along the line H-H′ in FIG. 23. FIG. 24 is a cross-sectional view taken along the line I-I in FIG. 26. FIG. 25 is a cross-sectional view taken along the line J-J′ in FIG. 26.

Referring to FIGS. 21 to 23, first, processes the same as or similar to the processes described with reference to FIG. 4 may be performed to from a second redistribution wiring layer 220 on a carrier substrate C1, and then, a heat transfer dummy chip 600 and a plurality of through plugs 610 as heat transfer mediums may be formed on the second redistribution wiring layer 220.

In some example embodiments of the present inventive concept, the plurality of through plugs 610 may be formed in a second region R2 of the second redistribution wiring layer 220, and the heat transfer dummy chip 600 may be formed in a first region R1 of the second redistribution wiring layer 220. The plurality of through plugs 610 may be arranged in the second region R2 and may be adjacent to the heat transfer dummy chip 600.

As illustrated in FIGS. 22 and 23, processes the same as or similar to the processes described with reference to FIGS. 5 to 7 may be performed to form the plurality of through plugs 610 in the second region R2 on a second surface 221b of the second redistribution wiring layer 220.

As illustrated in FIGS. 21 and 23, the heat transfer dummy chip 600 may be disposed in the first region R1 and on the second surface 221b of the second redistribution wiring layer 220. The heat transfer dummy chip 600 may be attached to the second surface 221b of the second redistribution wiring layer 220 by an adhesive film. For example, the adhesive film may include a thermal interface adhesive film, a die attach film (DAF), etc. The heat transfer dummy chip 600 may include a material having a relatively high heat transfer coefficient. For example, the heat transfer dummy chip 600 may be formed by sawing a silicon wafer.

Referring to FIGS. 24 to 26, processes the same as or similar to the processes described with reference to FIG. 8 may be performed to mount a plurality of third semiconductor chips 400b in the second region R2 and on the second surface 221b of the second redistribution wiring layer 220, and processes the same as or similar to the processes described with reference to FIGS. 9 to 11 may be performed to form a first sealing member 510 on the second surface 221b of the second redistribution wiring layer 220 to cover the plurality of third semiconductor chips 400b, the heat transfer dummy chip 600 and the plurality of through plugs 610.

In some example embodiments of the present inventive concept, the plurality of third semiconductor chips 400b may be spaced apart from each other in the second region R2 on the second surface 221b of the second redistribution wiring layer 220. The plurality of third semiconductor chips 400b may be spaced apart from each other along a circumference of the first region R1.

The first sealing member 510 may be formed to expose an upper surface of the heat transfer dummy chip 600. The first sealing member 510 may be formed to expose upper surfaces of the plurality of through plugs 610. The through plugs 610 may be through mold vias (TMVs) formed to extend through the first sealing member 510.

The heat transfer dummy chip 600 may be disposed in the first region R1 overlapping the first semiconductor chip 300, which is mounted on the first surface 221a of the second redistribution wiring layer 220, and may serve as a heat dissipation passage for dissipating heat from the front surface of the first semiconductor chip 300 in a downward direction to the outside.

The through plugs 610 may be disposed in the second region R2 overlapping with at least one of the second semiconductor chips 400a, which are mounted on the first surface 221a of the second redistribution wiring layer 220, and may serve as heat dissipation passages for dissipating heat from the front surface of the at least one of the second semiconductor chips 400a in a downward direction to the outside. Additionally, the through plugs 610 may serve as electrical passages for electrically connecting the first semiconductor chip 300, the second semiconductor chips 400a and the third semiconductor chips 400b to an external device.

Then, processes the same as or similar to the described with reference to FIG. 12 may be performed to mount a first semiconductor chip 300 and a plurality of second semiconductor chips 400a on a first surface 221a of the second redistribution wiring layer 220, and processes the same as or similar to the processes described with reference to FIGS. 13 and 14 may be performed to form a second sealing member 520 on a first surface 221a of the second redistribution wiring layer 220 to cover the first semiconductor chip 300 and the plurality of second semiconductor chips 400a.

Then, processes the same as or similar to the processes described with reference to FIGS. 13 to 16 may be performed to form a first redistribution wiring layer 210 on the first sealing member 510. Accordingly, an interposer 200 having the first and second redistribution wiring layers 210 and 220 may be formed.

Then, the interposer 200 may be mounted on a package substrate 100 via conductive connection members, and external connection members such as solder balls may be formed on external connection pads on a lower surface of the package substrate 100 to form the semiconductor package of FIGS. 17 and 18.

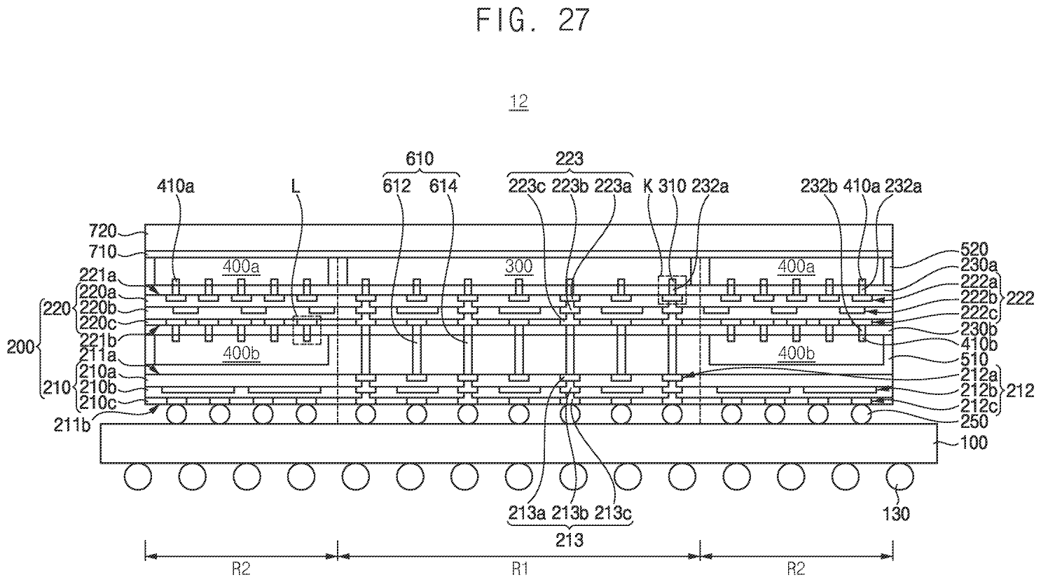

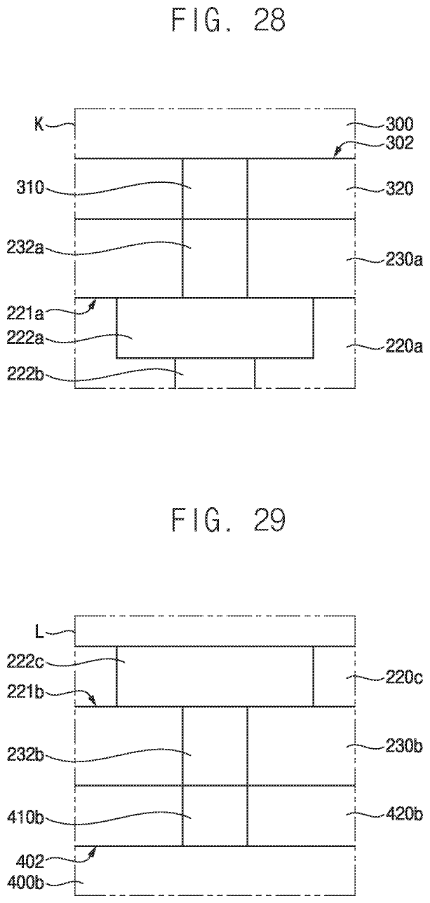

FIG. 27 is a cross-sectional view illustrating a semiconductor package in accordance with an example embodiment of the present inventive concept. FIG. 28 is an enlarged cross-sectional view illustrating portion ‘K’ in FIG. 27. FIG. 29 is an enlarged cross-sectional view illustrating portion ‘L’ in FIG. 27. The semiconductor package may be substantially the same as the semiconductor package described with reference to FIGS. 1 to 3 except for a mounting method of first, second and third semiconductor chips. Thus, same reference numerals may be used to refer to the same or like elements throughout the specification and any further repetitive explanation concerning the above elements may be omitted or briefly discussed.

Referring to FIGS. 27 to 29, an interposer 200 of a semiconductor package 12 may include a first redistribution wiring layer 210, a second redistribution wiring layer 220, which is stacked on the first redistribution wiring layer 210, a first semiconductor chip 300 and a plurality of second semiconductor chips 400a, which are disposed on the second redistribution wiring layer 220, and a plurality of third semiconductor chips 400b and a plurality of heat transfer plugs 610, which are disposed between the first redistribution wiring layer 210 and the second redistribution wiring layer 220.

In some example embodiments of the present inventive concept, the first semiconductor chip 300, the plurality of second semiconductor chips 400a and the plurality of third semiconductor chips 400b may be mounted on the redistribution wiring layer 220 by a hybrid copper bonding (HCB) method.

As illustrated in FIG. 28, the first semiconductor chip 300 may be mounted on the second redistribution wiring layer 220 using a hybrid copper bonding (HCB) method.

A first bonding pad 232a may be provided on a first upper redistribution wiring 222a of the second redistribution wiring layer 220, and a first passivation layer 230a may be formed on a first surface 221a of the second redistribution wiring layer 220 to expose at least a portion of the first bonding pad 232a. A first insulating layer 320 may be provided on a front surface 302 of the first semiconductor chip 300 to expose at least a portion of a first chip pad 310. The first passivation layer 230a and the first insulating layer 320 may include, for example, silicon oxide, carbon-doped silicon oxide, silicon carbonitride (SiCN), etc.

The front surface 302 of the first semiconductor chip 300 may face the first surface 221a of the second redistribution wiring layer 220. The first passivation layer 230a and the first insulating layer 320 may be bonded to each other. For example, the first passivation layer 230a and the first insulating layer 320 may be directly bonded to each other. Accordingly, the first chip pad 310 and the first bonding pad 232a are bonded to each other between the first semiconductor chip 300 and the second redistribution wiring layer 220 by Cu—Cu Hybrid Bonding (pad to pad direct bonding).

Outermost insulating layers of the first passivation layer 230a and the first insulating layer 320 may contact each other to provide a bonding structure having relatively high bonding strength. The first passivation layer 230a and the first insulating layer 320 may be bonded to each other by a high-temperature annealing process while in contact with each other. At this time, the bonding structure may have a relatively stronger bonding strength by covalent bonding.

As illustrated in FIG. 29, the plurality of third semiconductor chips 400b may be mounted on the second redistribution wiring layer 220 by a hybrid copper bonding (HCB) method.

A second bonding pad 232b may be provided on a third upper redistribution wiring 222c of the second redistribution wiring layer 220, and a second passivation layer 230b may be formed on a second surface 221b of the second redistribution wiring layer 220 to expose at least a portion of the second bonding pad 232b. A second insulating layer 420b may be provided on a front surface 402 of the third semiconductor chip 400b to expose at least a portion of a third chip pad 410b. The second passivation layer 230b and the second insulating layer 420b may include, for example, silicon oxide, carbon-doped silicon oxide, silicon carbonitride (SiCN), etc.

The front surface 402 of the third semiconductor chip 400b may face the second surface 221b of the second redistribution wiring layer 220. The second passivation layer 230b and the second insulating layer 420b may be bonded to each other. For example, the second passivation layer 230b and the second insulating layer 420b may be directly bonded to each other. Accordingly, the third chip pad 410b and the second bonding pad 232b may be bonded to each other between the third semiconductor chip 400b and the second redistribution wiring layer 220 by Cu—Cu Hybrid Bonding (pad to pad direct bonding).

Similarly, the plurality of second semiconductor chips 400a may be mounted on the second redistribution wiring layer 220 by a hybrid copper bonding (HCB) method.

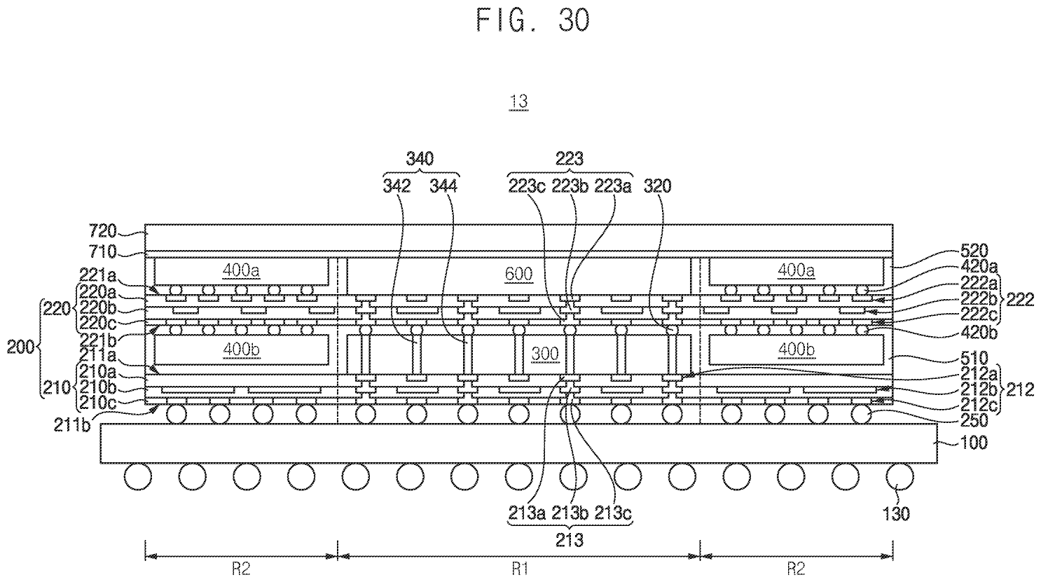

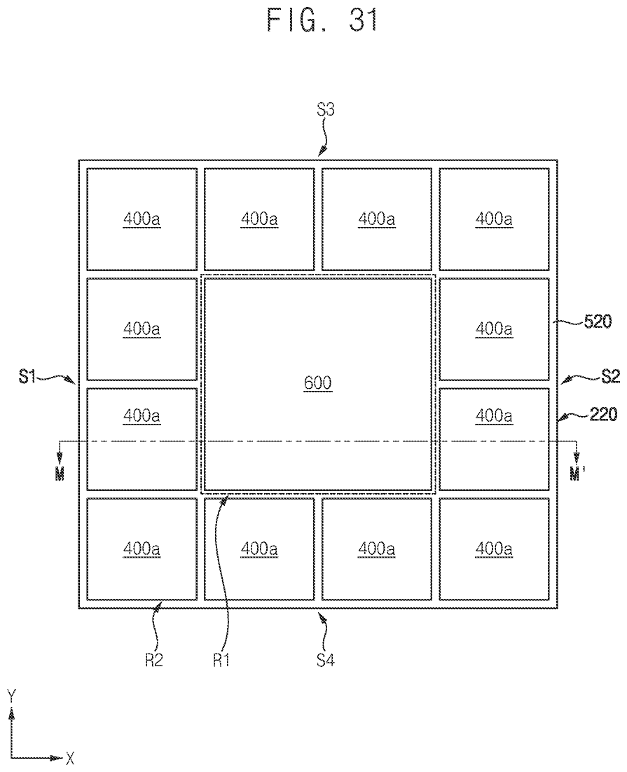

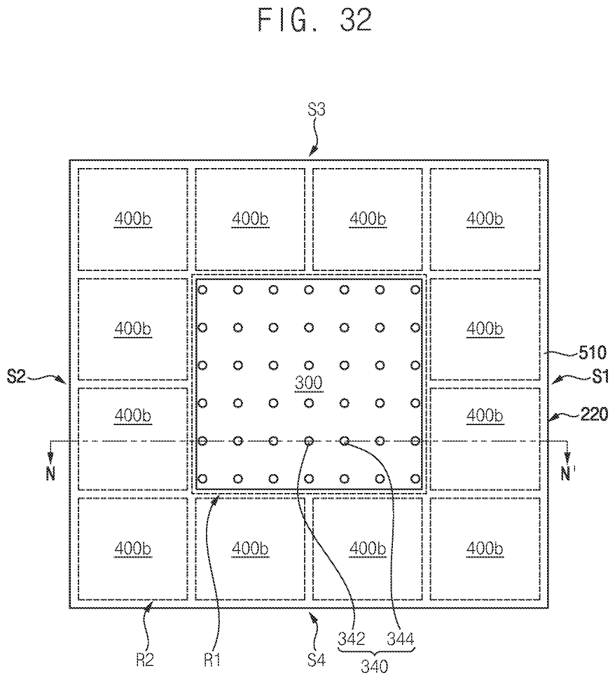

FIG. 30 is a cross-sectional view illustrating a semiconductor package in accordance with an example embodiment of the present inventive concept. FIG. 31 is a plan view illustrating a heat transfer dummy chip and a plurality of second semiconductor chips disposed on an upper surface of a second redistribution wiring layer in FIG. 30. FIG. 32 is a plan view illustrating a first semiconductor chip and a plurality of third semiconductor chips disposed on a lower surface of the second redistribution wiring layer in FIG. 30. FIG. 30 is a cross-sectional view taken along the line M-M′ in FIG. 31 and the line N-N′ in FIG. 32. The semiconductor package may be substantially the same as the semiconductor package described with reference to FIGS. 1 to 3 except for an arrangement of a first semiconductor chip and an additional configuration of a heat transfer dummy chip. Thus, same reference numerals may be used to refer to the same or like elements throughout the specification and further repetitive explanation concerning the above elements may be omitted or briefly discussed.

Referring to FIGS. 30 to 32, an interposer 200 of a semiconductor package 13 may include a first redistribution wiring layer 210, a second redistribution wiring layer 220, which is stacked on the first redistribution wiring layer 210, a heat transfer dummy chip 600 and a plurality of second semiconductor chips 400a disposed on the second redistribution wiring layer 220, and a first semiconductor chip 300 and a plurality of third semiconductor chips 400b disposed between the first redistribution wiring layer 210 and the second redistribution wiring layer 220.

In some example embodiments of the present inventive concept, the heat transfer dummy chip 600 may be arranged in a first region R1 and on a first surface 221a of the second redistribution wiring layer 220, and the plurality of second semiconductor chips 400a may be spaced apart from each other in a second region R2 and on the first surface 221a of the second redistribution wiring layer 220. The plurality of second semiconductor chips 400a may be spaced apart from each other along a perimeter of the heat transfer dummy chip 600.

The heat transfer dummy chip 600 may be attached to the first surface 221a of the second redistribution wiring layer 220 by an adhesive film. The plurality of second semiconductor chips 400a may be mounted on the first surface 221a of the second redistribution wiring layer 220 by flip chip bonding. The second semiconductor chip 400a may be arranged such that a front surface, i.e., an active surface, on which second chip pads are formed, faces the second redistribution wiring layer 220. The second chip pads of the second semiconductor chips 400a may be electrically connected to second redistribution wirings 222 of the second redistribution wiring layer 220 by second conductive bumps 420a.

In some example embodiments of the present inventive concept, the first semiconductor chip 300 may be arranged in the first region R1 and on a second surface 221b of the second redistribution wiring layer 220, and the plurality of third semiconductor chips 400b may be spaced apart from each other within the second region R2 and on the second surface 221b of the second redistribution wiring layer 220. The plurality of third semiconductor chips 400b may be spaced apart from each other along a perimeter of the first semiconductor chip 300.

The first semiconductor chip 300 and the plurality of third semiconductor chips 400b may be mounted on the second surface 221b of the second redistribution wiring layer 220 by a flip chip bonding method. The first semiconductor chip 300 may be arranged such that a front surface, i.e., an active surface, on which first chip pads are formed, faces the second redistribution wiring layer 220. The first chip pads of the first semiconductor chip 300 may be electrically connected to the second redistribution wirings 222 of the second redistribution wiring layer 220 by first conductive bumps 320. The third semiconductor chip 400b may be arranged such that a front surface, i.e., an active surface, on which third chip pads are formed, faces the second redistribution wiring layer 220. The third chip pads of the third semiconductor chips 400b may be electrically connected to the second redistribution wirings 222 of the second redistribution wiring layer 220 by the third conductive bumps 420b.

In some example embodiments of the present inventive concept, the heat transfer dummy chip 600 may be arranged on the first surface 221a of the second redistribution wiring layer 220 to overlap the first semiconductor chip 300. The first semiconductor chip 300 may include a plurality of through electrodes 340 formed therein. The through electrodes 340 may be through silicon vias (TSVs) formed to extend through a substrate of the first semiconductor chip 300. First redistribution wirings 212 of the first redistribution wiring layer 210 and the second redistribution wirings 222 of the second redistribution wiring layer 220 may be electrically connected to each other by the through electrodes 340.

The plurality of through electrodes 340 may include a first group of through electrodes 342 and a second group of through electrodes 344. The first group of through electrodes 342 may be electrically connected to circuit elements of the first semiconductor chip 300, and the second group of through electrodes 344 may be electrically insulated from the circuit elements of the first semiconductor chip 300.

A first sealing member 510 may be provided on the second surface 221b of the second redistribution wiring layer 220 to cover the first semiconductor chip 300 and the plurality of third semiconductor chips 400b. A rear surface, i.e., a lower surface, of the first semiconductor chip 300 may be exposed by the first sealing member 510. The first redistribution wiring layer 210 may be provided on the first sealing member 510 and the rear surface of and the first semiconductor chip 300 exposed by the first sealing member 510. For example, the first sealing member 510 may be disposed between the second redistribution wiring layer 220 and the first redistribution wiring layer 210. The first redistribution wirings 212 of the first redistribution wiring layer 210 may be electrically connected to the through electrodes 340 of the first semiconductor chip 300.

As mentioned above, the heat transfer dummy chip 600 may be arranged in the first region R1 overlapping the first semiconductor chip 300 and may serve as a heat dissipation passage for dissipating heat from the front surface of the first semiconductor chip 300 upward to the outside. Further, the plurality of through electrodes 340 of the first semiconductor chip 300 may serve as heat dissipation passages for transferring heat dissipated downward from the rear surface of the first semiconductor chip 300 to the outside through the first redistribution wiring layer 210 below.

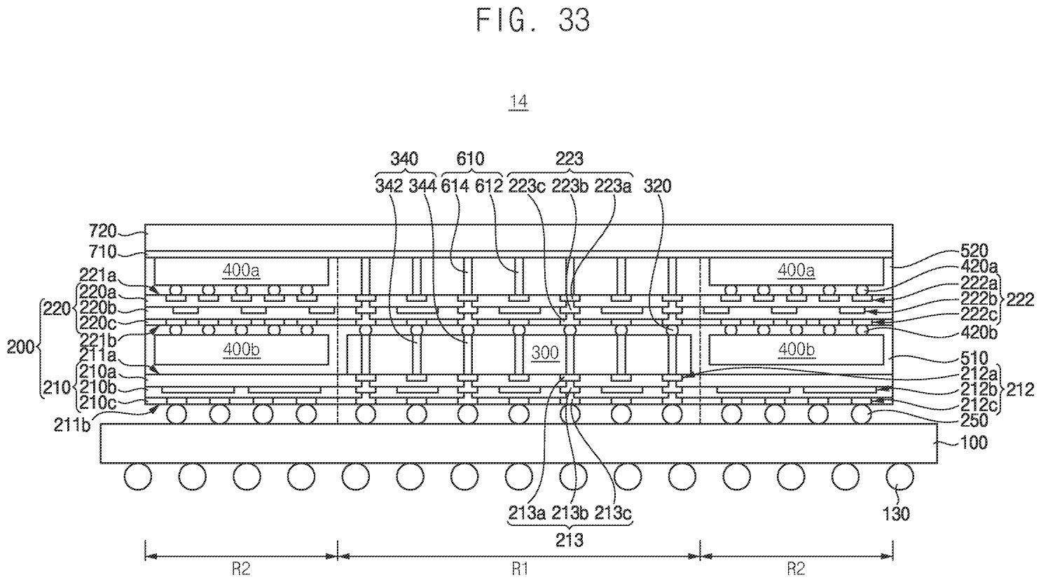

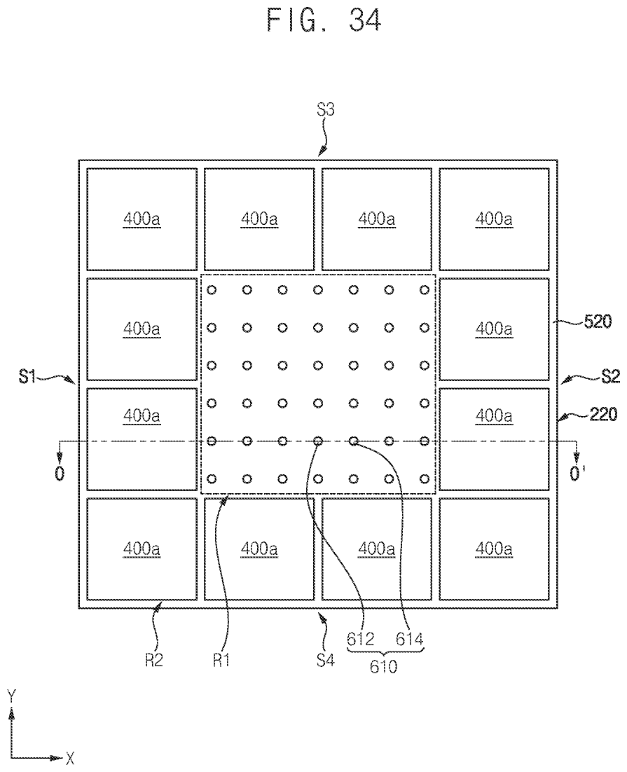

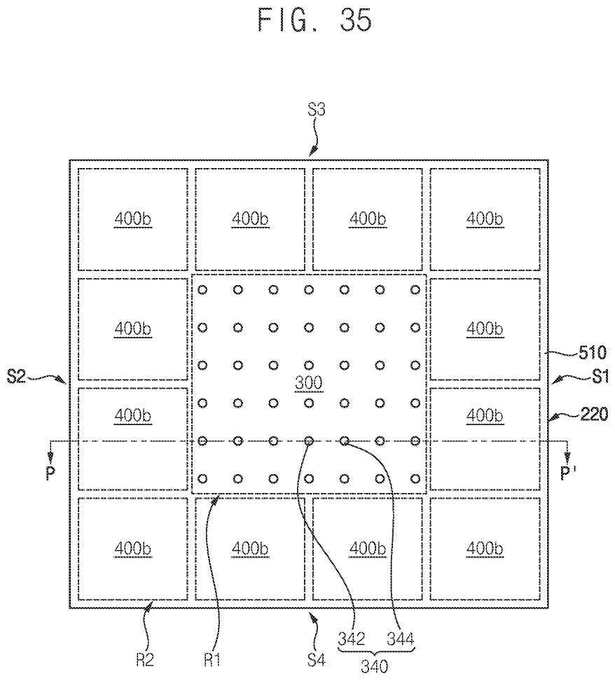

FIG. 33 is a cross-sectional view illustrating a semiconductor package in accordance with an example embodiment of the present inventive concept. FIG. 34 is a plan view illustrating heat transfer plugs and a plurality of second semiconductor chips disposed on an upper surface of a second redistribution wiring layer in FIG. 33. FIG. 35 is a plan view illustrating a first semiconductor chip and a plurality of third semiconductor chips disposed on a lower surface of the second redistribution wiring layer in FIG. 33. The semiconductor package may be substantially the same as the semiconductor package described with reference to FIGS. 30 to 32 except for configurations of heat transfer plugs instead of heat transfer dummy chips. Thus, same reference numerals may be used to refer to the same or like elements throughout the specification and any further repetitive explanation concerning the above elements may be omitted or briefly discussed.

Referring to FIGS. 33 to 35, an interposer 200 of a semiconductor package 14 may include a first redistribution wiring layer 210, a second redistribution wiring layer 220, which is stacked on the first redistribution wiring layer 210, heat transfer plugs 610 and a plurality of second semiconductor chips 400a, which are disposed on the second redistribution wiring layer 220, and a first semiconductor chip 300 and a plurality of third semiconductor chips 400b that are disposed between the first redistribution wiring layer 210 and the second redistribution wiring layer 220.

In some example embodiments of the present inventive concept, the heat transfer plugs 610 may be disposed in a first region R1 and on a first surface 221a of the second redistribution wiring layer 220, and the plurality of second semiconductor chips 400a may be spaced apart from each other within the second region R2 and on the first surface 221a of the second redistribution wiring layer 220. The plurality of second semiconductor chips 400a may be spaced apart from each other along a perimeter of the heat transfer plugs 610.

The first semiconductor chip 300 may be arranged in the first region R1 and on a second surface 221b of the second redistribution wiring layer 220, and the plurality of third semiconductor chips 400b may be spaced apart from each other within the second region R2 on the second surface 221b of the second redistribution wiring layer 220. The plurality of third semiconductor chips 400b may be spaced apart from each other along a perimeter of the first semiconductor chip 300.

The first semiconductor chip 300 and the plurality of third semiconductor chips 400b may be mounted on the second surface 221b of the second redistribution wiring layer 220 by a flip chip bonding method. The first semiconductor chip 300 may be arranged such that a front surface, i.e., an active surface, on which first chip pads are formed, faces the second redistribution wiring layer 220. The first chip pads of the first semiconductor chip 300 may be electrically connected to second redistribution wirings 222 of the second redistribution wiring layer 220 by first conductive bumps 320. The third semiconductor chip 400b may be arranged such that a front surface, i.e., an active surface, on which third chip pads are formed, faces the second redistribution wiring layer 220. The third chip pads of the third semiconductor chips 400b may be electrically connected to the second redistribution wirings 222 of the second redistribution wiring layer 220 by third conductive bumps 420b.

In some example embodiments of the present inventive concept, the heat transfer plugs 610 may be formed on the first surface 221a of the second redistribution wiring layer 220 to overlap the first semiconductor chip 300 with the second redistribution wiring layer 220 interposed between the first semiconductor chip 300 and the heat transfer plugs 610. The first semiconductor chip 300 may include a plurality of through electrodes 340 formed therein. The through electrodes 340 may be through silicon vias (TSVs) formed to extend through a substrate of the first semiconductor chip 300. First redistribution wirings 212 of the first redistribution wiring layer 210 and the second redistribution wirings 222 of the second redistribution wiring layer 220 may be electrically connected to each other through the through electrodes 340.

In some example embodiments of the present inventive concept, a second sealing member 520 may be provided on the first surface 221a of the second redistribution wiring layer 220 to cover the heat transfer plugs 610 and the plurality of third semiconductor chips 400b. Upper surfaces of the heat transfer plugs 610 may be exposed by the second sealing member 520.

A heat dissipation plate 720 may be attached to the second sealing member 520 using a thermal interface material 710. The heat dissipation plate 720 may be disposed on upper surfaces of the plurality of second semiconductor chips 400a and the heat transfer plugs 610 that are exposed by the second sealing member 520. Accordingly, heat from the front surface of the first semiconductor chip 300 may be dissipated upward through the heat transfer plugs 610 and the heat dissipation plate 720 to the outside.

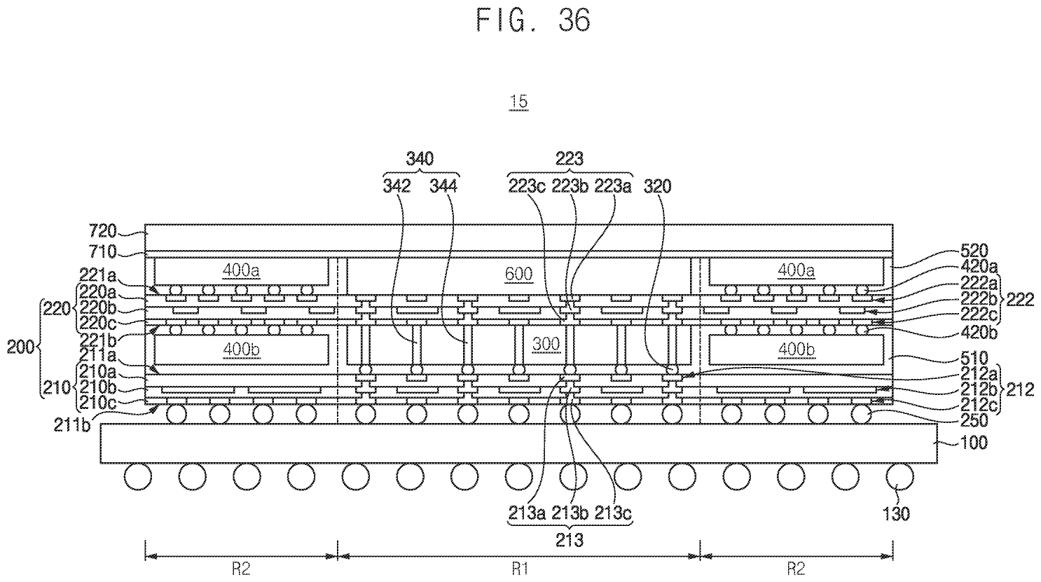

FIG. 36 is a cross-sectional view illustrating a semiconductor package in accordance with an example embodiment of the present inventive concept. The semiconductor package may be substantially the same as the semiconductor package described with reference to FIGS. 30 to 32 except for a mounting method of a first semiconductor chip. Thus, same reference numerals may be used to refer to the same or like elements throughout the specification and any further repetitive explanation concerning the above elements may be omitted or briefly discussed.

Referring to FIG. 36, an interposer 200 of a semiconductor package 15 may include a first redistribution wiring layer 210, a second redistribution wiring layer 220, which is stacked on the first redistribution wiring layer 210, a heat transfer dummy chip 600 and a plurality of second semiconductor chips 400a, which are disposed on the second redistribution wiring layer 220, and a first semiconductor chip 300 and a plurality of third semiconductor chips 400b, which are disposed between the first redistribution wiring layer 210 and the second redistribution wiring layer 220.

In some example embodiments of the present inventive concept, the first semiconductor chip 300 may be arranged in a first region R1 and on a second surface 221b of the second redistribution wiring layer 220. The first semiconductor chip 300 may be mounted on a first surface 211a of the first redistribution wiring layer 210 by a flip chip bonding method. The first semiconductor chip 300 may be arranged such that a front surface, i.e., an active surface, on which first chip pads are formed, faces the first redistribution wiring layer 210.

The first chip pads of the first semiconductor chip 300 may be electrically connected to the first redistribution wirings 212 of the first redistribution wiring layer 210 by first conductive bumps 320. In addition, as an example, the first chip pads of the first semiconductor chip 300 may be electrically directly connected to the first redistribution wirings 212 of the first redistribution wiring layer 210 without using the first conductive bumps 320 as a medium.

In some example embodiments of the present inventive concept, the first semiconductor chip 300 may include a plurality of through electrodes 340 formed therein. The through electrodes 340 may be through silicon vias (TSVs) formed to extend through a substrate of the first semiconductor chip 300. The first redistribution wirings 212 of the first redistribution wiring layer 220 and second redistribution wirings 222 of the second redistribution wiring layer 220 may be electrically connected to each other through the through electrodes 340.

The plurality of through electrodes 340 may include a first group of through electrodes 342 and a second group of through electrodes 344. The first group of through electrodes 342 may be electrically connected to circuit elements of the first semiconductor chip 300, and the second group of through electrodes 614 may be electrically insulated from the circuit elements of the first semiconductor chip 300.

The heat transfer dummy chip 600 may be arranged in a first region R1 overlapping the first semiconductor chip 300 and may serve as heat dissipation passages for dissipating heat dissipated upward from the rear surface of the first semiconductor chip 300 to the outside. In addition, heat dissipated in a downward direction from the front surface of the first semiconductor chip 300 may be transferred to the outside through the first redistribution wiring layer 210.

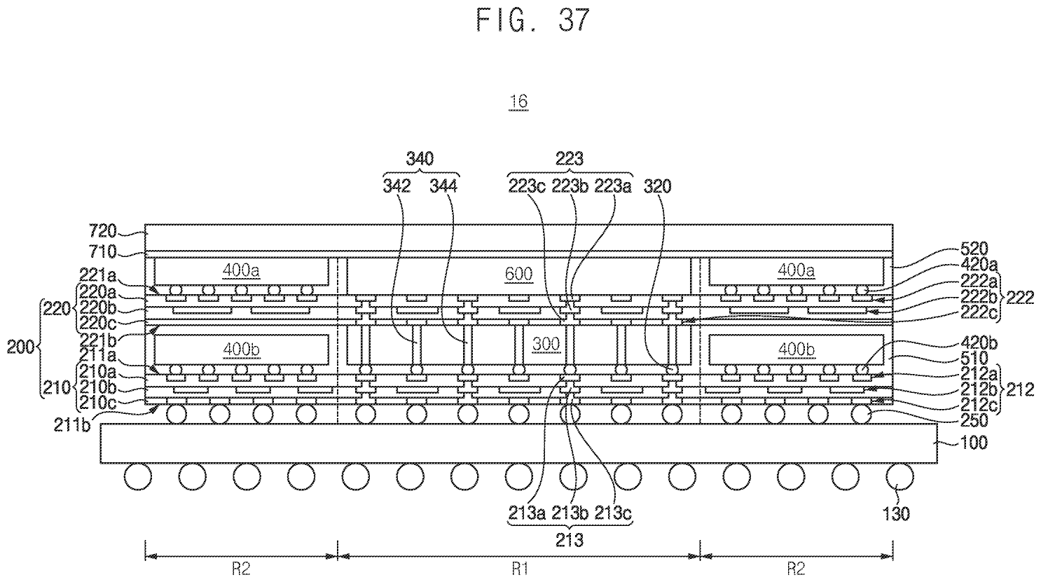

FIG. 37 is a cross-sectional view illustrating a semiconductor package in accordance with an example embodiment of the present inventive concept. The semiconductor package may be substantially the same as the semiconductor package described with reference to FIG. 36 except for a mounting method of a plurality of third semiconductor chips. Thus, same reference numerals may be used to refer to the same or like elements throughout the specification and any further repetitive explanation concerning the above elements may be omitted or briefly discussed.

Referring to FIG. 37, an interposer 200 of a semiconductor package 16 may include a first redistribution wiring layer 210, a second redistribution wiring layer 220, which is stacked on the first redistribution wiring layer 210, and a heat transfer dummy chip 600 and a plurality of second semiconductor chips 400a that are disposed on the second redistribution wiring layer 220, and the first semiconductor chip 300 and the plurality of third semiconductor chips 400b that are disposed between the first redistribution wiring layer 210 and the second redistribution wiring layer 220.

In some example embodiments of the present inventive concept, the first semiconductor chip 300 and the plurality of third semiconductor chips 400b may be mounted on a first surface 211a of the first redistribution wiring layer 210 by a flip chip bonding method.

The first semiconductor chip 300 may be arranged such that a front surface, i.e., an active surface, on which first chip pads are formed, faces the first redistribution wiring layer 210. The first chip pads of the first semiconductor chip 300 may be electrically connected to first redistribution wirings 212 of the first redistribution wiring layer 210 by first conductive bumps 320. The third semiconductor chip 400b may be arranged such that a front surface, i.e., an active surface, on which third chip pads are formed, faces the first redistribution wiring layer 210. The third chip pads of the third semiconductor chip 400b may be electrically connected to the first redistribution wirings 212 of the first redistribution wiring layer 210 by third conductive bumps 420b.

The semiconductor package may include semiconductor devices such as logic devices or memory devices. The semiconductor package may include logic devices such as central processing units (CPUs), main processing units (MPUs), or application processors (APs), or the like, and volatile memory devices such as DRAM devices, HBM devices, or non-volatile memory devices such as flash memory devices, PRAM devices. MRAM devices, ReRAM devices, or the like.

While the present inventive concept has been described with reference to example embodiments thereof, it will be understood by those of ordinary skill in the art that various changes in form and details may be made thereto without departing from the spirit and scope of the present inventive concept.

What is claimed is:

1. A semiconductor package, comprising:
a first redistribution wiring layer having first redistribution wirings;
a second redistribution wiring layer arranged on the first redistribution wiring layer, and including a first region and a second region, wherein the second redistribution wiring layer includes second redistribution wirings;
a first semiconductor chip arranged on one of an upper surface or a lower surface of the first region of the second redistribution wiring layer;
a plurality of second semiconductor chips spaced apart from each other on the upper surface of the second region of the second redistribution wiring layer;
a plurality of third semiconductor chips arranged in the second region of the second redistribution wiring layer and spaced apart from each other between the first and second redistribution wiring layers; and
a heat transfer medium arranged on one of the upper surface or the lower surface of the first region of the second redistribution wiring layer and overlapping the first semiconductor chip with the second redistribution wiring layer interposed between the first semiconductor chip and the heat transfer medium.

2. The semiconductor package of claim 1, wherein the second region at least partially surrounds the first region.

3. The semiconductor package of claim 1, wherein the heat transfer medium includes a plurality of through plugs that extend in a vertical direction from the lower surface or the upper surface of the second redistribution wiring layer.

4. The semiconductor package of claim 3, wherein the plurality of through plugs are electrically connected to the second redistribution wirings.

5. The semiconductor package of claim 3, wherein the plurality of through plugs include a first group of through plugs and a second group of through plugs, wherein the first group of through plugs is electrically connected to the first semiconductor chip, and the second group of through plugs is electrically insulated from the first semiconductor chip.

6. The semiconductor package of claim 1, wherein the heat transfer medium includes a dummy chip disposed on the lower surface or the upper surface of the second redistribution wiring layer.

7. The semiconductor package of claim 6, wherein the first semiconductor chip is arranged on the lower surface of the first region of the second redistribution wiring layer, wherein the first semiconductor chip includes a plurality of through electrodes formed therein, and the first and second redistribution wirings are electrically connected to each other by the through electrodes.

8. The semiconductor package to claim 1, further comprising:
a first sealing member disposed on the lower surface of the second redistribution wiring layer and covering the plurality of third semiconductor chips; and
a second sealing member disposed on the upper surface of the second redistribution wiring layer and covering the plurality of second semiconductor chips.

9. The semiconductor package of claim 1, wherein each of the first semiconductor chip, the plurality of second semiconductor chips, and the plurality of third semiconductor chips are mounted on the second redistribution wiring layer via conductive bumps.

10. The semiconductor package of claim 1, wherein chip pads of each of the first semiconductor chip, the plurality of second semiconductor chips, and the plurality of third semiconductor chips are bonded to bonding pads of the second redistribution wiring layer.

11. A semiconductor package, comprising:
an upper redistribution wiring layer including a first region and a second region at least partially surrounding the first region, and having upper redistribution wirings;
a first semiconductor chip arranged on one of an upper surface or a lower surface of the first region of the upper redistribution wiring layer;
a plurality of second semiconductor chips spaced apart from each other on an upper surface of the second region of the upper redistribution wiring layer;
a plurality of third semiconductor chips spaced apart from each other on a lower surface of the second region of the upper redistribution wiring layer;
a first sealing member disposed on the plurality of third semiconductor chips and disposed on the upper redistribution wiring layer;
a heat transfer medium arranged on one of the upper surface or the lower surface of the first region of the upper redistribution wiring layer and overlapping the first semiconductor chip, wherein the heat transfer medium is provided in the first sealing member; and
a lower redistribution wiring layer overlapping a lower surface of the first sealing member and having lower redistribution wirings electrically connected to the upper redistribution wirings.

12. The semiconductor package of claim 11, wherein the heat transfer medium includes a plurality of through plugs that extend in a vertical direction from the lower surface or the upper surface of the upper redistribution wiring layer.

13. The semiconductor package of claim 12, wherein the plurality of through plugs are electrically connected to the upper redistribution wirings.

14. The semiconductor package of claim 12, wherein the plurality of through plugs include a first group of through plugs and a second group of through plugs, wherein the first group of through plugs is electrically connected to the first semiconductor chip, and the second group of through plugs is electrically insulated from the first semiconductor chip.

15. The semiconductor package of claim 11, wherein the heat transfer medium includes a dummy chip arranged on the lower surface or the upper surface of the upper redistribution wiring layer.

16. The semiconductor package of claim 11, wherein each of the first semiconductor chip, the plurality of second semiconductor chips, and the plurality of third semiconductor chips are mounted on the upper redistribution wiring layer via conductive bumps.

17. The semiconductor package of claim 11, wherein chip pads of each of the first semiconductor chip, the plurality of second semiconductor chips, and the plurality of third semiconductor chips are bonded to bonding pads of the upper redistribution wiring layer.

18. The semiconductor package of claim 11, further comprising:
a second sealing member covering the first semiconductor chip and the plurality of second semiconductor chips and disposed on the upper surface of the upper redistribution wiring layer.

19. The semiconductor package of claim 18, further comprising:
a heat dissipation plate disposed on the second sealing member via a thermal interface material.

20. A semiconductor package, comprising:
a package substrate;
a first redistribution wiring layer mounted on the package substrate via conductive bumps and having first redistribution wirings;
a second redistribution wiring layer arranged on the first redistribution wiring layer, and including a first region and a second region at least partially surrounding the first region, wherein the second redistribution wiring layer has second redistribution wirings;
a first semiconductor chip mounted on an upper surface of the first region of the second redistribution wiring layer;
a plurality of second semiconductor chips mounted on an upper surface of the second region of the second redistribution wiring layer and spaced apart from each other;
a plurality of third semiconductor chips mounted on a lower surface of the second region of the second redistribution wiring layer and spaced apart from each other between the first and second redistribution wiring layers;
a first sealing member covering the plurality of third semiconductor chips and disposed on the lower surface of the second redistribution wiring layer;
a second sealing member covering the first semiconductor chip and the plurality of second semiconductor chips and disposed on the upper surface of the second redistribution wiring layer; and
a plurality of through plugs extending to penetrate the first sealing member, which is disposed on a lower surface of the first region of the second redistribution wiring layer, and electrically connecting the first and second redistribution wirings to each other.
